(19) United States
(12) Patent Application Publication
(10) Pub. No.: US 2026/0282984 A1
(43) Pub. Date: Sep. 17, 2026

(54) SEMICONDUCTOR PACKAGE AND ELECTRONIC SYSTEM INCLUDING THE SAME

(71) Applicant: SAMSUNG ELECTRONICS CO., LTD., Suwon-si (KR)

(72) Inventors: Jaesung KIM, Suwon-si (KR); Seungmin KIM, Suwon-si (KR)

(73) Assignee: SAMSUNG ELECTRONICS CO., LTD., Suwon-si (KR)

(21) Appl. No.: 19/564,638

(22) Filed: Mar. 12, 2026

(30) Foreign Application Priority Data
Mar. 14, 2025 (KR) 10-2025-0033603

(51) Int. Cl. H10W 70/685; H10W 42/20; H10W 70/654; H10W 72/00; H10W 74/15; H10W 90/00; H10W 90/24

(52) U.S. Cl. CPC H10W 70/687; H10W 42/276; H10W 70/654; H10W 90/7295; H10W 72/884; H10W 74/15; H10W 90/24; H10W 90/722; H10W 90/724; H10W 90/734; H10W 90/752; H10W 90/754

(57) ABSTRACT

A semiconductor package includes a package substrate including a substrate base, an upper solder resist layer covering the upper surface of the substrate base, and a lower solder resist layer covering the lower surface of the substrate base, at least one semiconductor chip attached onto the package substrate, a molding layer covering the upper surface of the package substrate and surrounding the at least one semiconductor chip, and an electromagnetic wave shielding layer covering the package substrate and the molding layer, in which a lower surface of the lower solder resist layer has a first lower surface region having a first arithmetic average roughness and a second lower surface region having a second arithmetic average roughness that is less than the first arithmetic average roughness.

### CROSS-REFERENCE TO RELATED APPLICATION

This application is based on and claims priority under 35 U.S.C. § 119 to Korean Patent Application No. 10-2025-0033603, filed on Mar. 14, 2025, in the Korean Intellectual Property Office, the disclosure of which is incorporated by reference herein in its entirety.

### BACKGROUND

The inventive concept relates to a semiconductor package and an electronic system including the same, and more particularly, to a semiconductor package including an electromagnetic wave shielding layer and an electronic system including the same.

According to the rapid development of the electronics industry and user needs, electronic devices are becoming more compact and have higher performance, and accordingly, semiconductor packages with electromagnetic shielding layers capable of shielding electromagnetic interference (EMI) between components included in electronic devices and electronic systems including semiconductor packages have been developed.

### SUMMARY

The inventive concept provides a semiconductor package with improved reliability by enabling electromagnetic wave shielding and an electronic system including the same.

According to an aspect of the inventive concept, there is provided a semiconductor package including a package substrate including a substrate base, a plurality of upper surface connection pads disposed on an upper surface of the substrate base, a plurality of lower surface connection pads disposed on a lower surface of the substrate base and electrically connected to the plurality of corresponding upper surface connection pads, an upper solder resist layer covering the upper surface of the substrate base, and a lower solder resist layer covering the lower surface of the substrate base, at least one semiconductor chip attached onto the package substrate and electrically connected to the plurality of upper surface connection pads, a plurality of package connection terminals attached onto the plurality of lower surface connection pads, a molding layer covering the upper surface of the package substrate and surrounding the at least one semiconductor chip, and an electromagnetic wave shielding layer covering the package substrate and the molding layer, in which a lower surface of the lower solder resist layer has a first lower surface region having a first arithmetic average roughness and a second lower surface region having a second arithmetic average roughness that is less than the first arithmetic average roughness, and the first lower surface region is spaced apart from the plurality of package connection terminals and disposed along an edge of the package substrate.

According to an aspect of the inventive concept, there is provided a semiconductor package including a package substrate comprising a substrate base, a plurality of upper surface connection pads disposed on an upper surface of the substrate base, a plurality of lower surface connection pads disposed on a lower surface of the substrate base and electrically connected to the plurality of corresponding upper surface connection pads, an upper solder resist layer covering the upper surface of the substrate base, and a lower solder resist layer covering the lower surface of the substrate base, at least one semiconductor chip attached onto the package substrate and electrically connected to the plurality of upper surface connection pads, a plurality of package connection terminals attached onto the plurality of lower surface connection pads, a molding layer covering the upper surface of the package substrate and surrounding the at least one semiconductor chip, and an electromagnetic wave shielding layer covering the package substrate and the molding layer, in which a lower surface of the lower solder resist layer has a first lower surface region having a first arithmetic average roughness and spaced apart from the plurality of package connection terminals, and a second lower surface region having a second arithmetic average roughness that is less than the first arithmetic average roughness, a first length, which is a shortest distance between the edge of the package substrate and the plurality of package connection terminals in a first horizontal direction, is less than a second length, which is a shortest distance between the edge of the package substrate and the plurality of package connection terminals in a second horizontal direction orthogonal to the first horizontal direction, and the first lower surface region has a horizontal width greater than or equal to ½ of the first length and is disposed along the edge of the package substrate.

According to an aspect of the inventive concept, there is provided an electronic system including a package substrate including a substrate base, a plurality of upper surface connection pads disposed on an upper surface of the substrate base, a plurality of lower surface connection pads disposed on a lower surface of the substrate base and electrically connected to the plurality of corresponding upper surface connection pads, an upper solder resist layer covering the upper surface of the substrate base, and a lower solder resist layer covering the lower surface of the substrate base; at least one semiconductor chip attached onto the package substrate and electrically connected to the plurality of upper surface connection pads; a plurality of package connection terminals attached onto the plurality of lower surface connection pads; a molding layer covering the upper surface of the package substrate and surrounding the at least one semiconductor chip; an electromagnetic wave shielding layer covering the package substrate and the molding layer; a system substrate including a system substrate base, a plurality of upper system connection pads disposed on an upper surface of the system substrate base, the plurality of package connection terminals being attached onto the plurality of upper system connection pads, an upper system solder resist layer covering the upper surface of the system substrate base, and a lower system solder resist layer covering a lower surface of the system substrate base, and a system underfill layer surrounding the plurality of package connection terminals and disposed between the package substrate and the system substrate, in which a lower surface of the lower solder resist layer has a first lower surface region having a first arithmetic average roughness and a second lower surface region having a second arithmetic average roughness that is less than the first arithmetic average roughness, the first lower surface region is spaced apart from the plurality of package connection terminals and disposed along an edge of the package substrate, and a part of an upper surface of the system underfill layer is in contact with the first lower surface region.

According to an aspect of the inventive concept, there is provided a method of manufacturing a semiconductor package including forming a package substrate including a substrate base, a plurality of upper surface connection pads disposed on an upper surface of the substrate base, a plurality of lower surface connection pads disposed on a lower surface of the substrate base and electrically connected to the plurality of corresponding upper surface connection pads, an upper solder resist layer covering the upper surface of the substrate base, and a lower solder resist layer covering the lower surface of the substrate base, performing surface treatment on a part of a lower surface of the lower solder resist layer disposed along an edge of the substrate base, attaching a semiconductor chip onto the package substrate, forming a molding layer covering an upper surface of the package substrate and surrounding the semiconductor chip, attaching a plurality of package connection terminals onto the plurality of lower surface connection pads, forming an adhesive layer surrounding the plurality of package connection terminals on a lower surface of the package substrate, forming a preliminary shielding layer covering side surfaces of the adhesive layer, side surfaces of the package substrate, and side surfaces and an upper surface of the molding layer, and forming an electromagnetic shielding layer covering a part of the preliminary shielding layer covering the side surfaces of the package substrate and the side surfaces and the upper surface of the molding layer by separating the adhesive layer from the package substrate, in which a lower surface of the lower solder resist layer has a first lower surface region, which is a part of the lower surface of the lower solder resist layer, having a first arithmetic average roughness and on which surface treatment is performed, and a second lower surface region, which is the remaining part of the lower surface of the lower solder resist layer, having a second arithmetic average roughness that is less than the first arithmetic average roughness, and the first lower surface region is spaced apart from the plurality of package connection terminals and disposed along the edge of the package substrate.

A first length, which is a shortest distance between the edge of the package substrate and the plurality of package connection terminals in a first horizontal direction, may be less than a second length, which is a shortest distance between the edge of the package substrate and the plurality of package connection terminals in a second horizontal direction orthogonal to the first horizontal direction, and, in the performing of the surface treatment, a horizontal width of the first lower surface region in the first horizontal direction may be greater than or equal to ½ of the first length and less than the first length.

In the performing of the surface treatment, a shortest distance between the first lower surface region and the plurality of package connection terminals may be greater than or equal to a horizontal width of each of the plurality of package connection terminals.

In the performing of the surface treatment, the lower surface of the lower solder resist layer may have at least two first lower surface regions spaced apart from each other with a part of the second lower surface region disposed therebetween.

In the performing of the surface treatment, a separation distance between the at least two first lower surface regions may be less than the horizontal width of the first lower surface region in the first horizontal direction.

In the performing of the surface treatment, the first lower surface region may have a rectangular ring shape extending continuously along the edge of the package substrate in a plan view.

In the performing of the surface treatment, a plurality of the first lower surface regions may be spaced apart from each other, and each of the plurality of first lower surface regions may have any one of an I-shape, an L-shape, and a U-shape in a plan view.

In the performing of the surface treatment, the first arithmetic average roughness may be at least twice greater than the second arithmetic average roughness.

In the performing of the surface treatment, the second arithmetic average roughness may be 50 nm or less, and the first arithmetic average roughness may be at least 60 nm greater than the second arithmetic average roughness.

In the forming of the electromagnetic shielding layer, the adhesive layer may be separated from the package substrate such that a part of the preliminary shielding layer covering the side surfaces of the adhesive layer remains on the side surfaces of the adhesive layer.

### BRIEF DESCRIPTION OF THE DRAWINGS

Embodiments will be more clearly understood from the following detailed description taken in conjunction with the accompanying drawings in which:

FIG. 1A is a cross-sectional view illustrating a semiconductor package according to embodiments, and FIG. 1B is a plan view illustrating a lower surface of the semiconductor package according to embodiments;

FIG. 2 is a cross-sectional view illustrating parts of a package substrate included in a semiconductor package according to embodiments;

FIGS. 3A and 3B are plan views illustrating lower surfaces of semiconductor packages according to embodiments;

FIGS. 4A, 4B, 4C, 4D, 4E, 4F, 4G, and 4H are plan views illustrating lower surfaces of semiconductor packages according to embodiments;

FIGS. 5A, 5B, 5C, 5D, 5E, 5F, and 5G are cross-sectional views illustrating a method of manufacturing a semiconductor package, according to an embodiment;

FIG. 6 is a cross-sectional view illustrating a semiconductor package according to embodiments;

FIG. 7 is a cross-sectional view illustrating a semiconductor package according to embodiments;

FIGS. 8A and 8B are cross-sectional views illustrating semiconductor packages according to embodiments;

FIGS. 9A and 9B are cross-sectional views illustrating semiconductor packages according to embodiments; and

FIG. 10 is a cross-sectional view illustrating an electronic system including a semiconductor package according to embodiments.

### DETAILED DESCRIPTION OF THE EMBODIMENTS

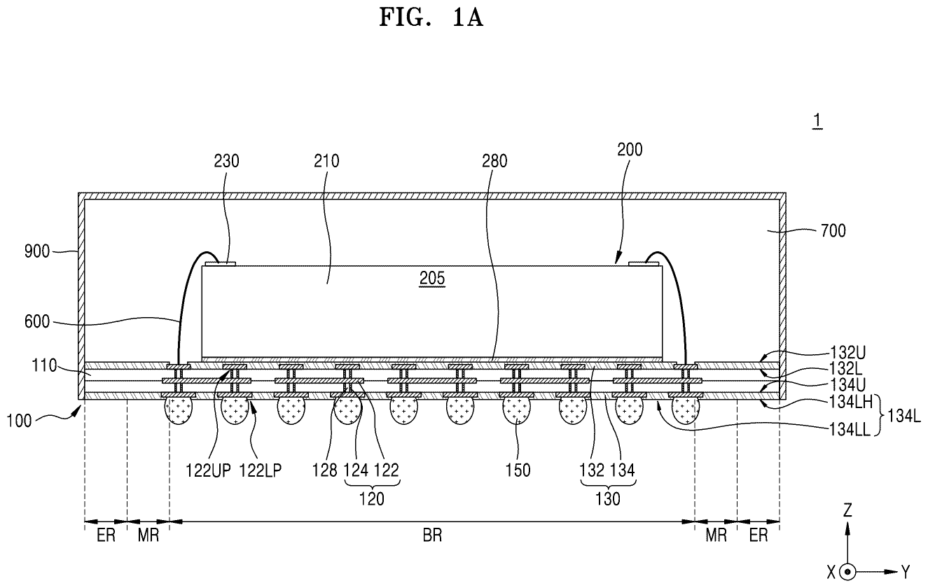

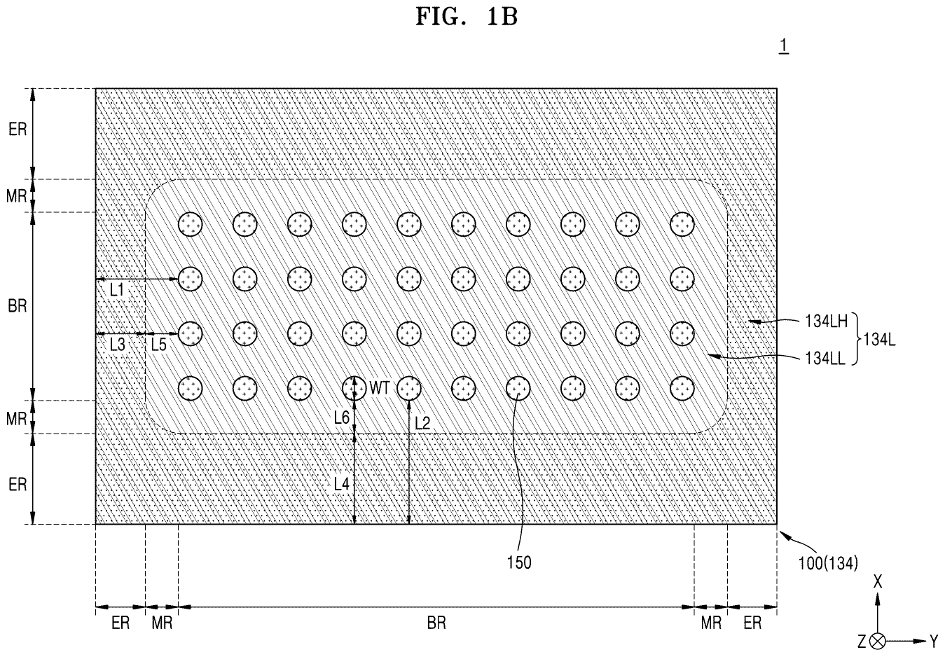

FIG. 1A is a cross-sectional view illustrating a semiconductor package according to embodiments, and FIG. 1B is a plan view illustrating a lower surface of the semiconductor package according to embodiments.

Referring to FIGS. 1A and 1B together, a semiconductor package 1 includes a package substrate 100, at least one semiconductor chip 200, a molding layer 700, and an electromagnetic wave shielding layer 900. The at least one semiconductor chip 200 may be attached onto the package substrate 100. The molding layer 700 may surround the at least one semiconductor chip 200 on the package substrate 100. The electromagnetic wave shielding layer 900 may cover the package substrate 100 and the molding layer 700.

In some embodiments, the package substrate 100 may be a printed circuit board. For example, the package substrate 100 may be a double-sided printed circuit board or a multi-layer printed circuit board. The package substrate 100 may include at least one substrate base 110 and a substrate wiring structure 120.

The substrate base 110 may include at least one material selected from phenol resin, epoxy resin, and polyimide. For example, the substrate base 110 may include at least one material selected from frame retardant 4 (FR-4), tetrafunctional epoxy, polyphenylene ether, epoxy/polyphenylene oxide, bismaleimide triazine (BT), thermount, cyanate ester, polyimide, and liquid crystal polymer.

In some embodiments, the package substrate 100 may include a plurality of stacked substrate bases 110. When the package substrate 100 includes the plurality of stacked substrate bases 110, the plurality of substrate bases 110 may include a core layer and one or more prepreg layers respectively stacked on an upper surface and a lower surface of the core layer. In some embodiments, the core layer and each of the prepreg layers may include the same material. The thickness of each of the one or more prepreg layers may be thinner than that of the core layer.

Herein, unless one substrate base 110 is specifically mentioned, the substrate base 110, the at least one substrate base 110, or the plurality of substrate bases 110 refers to the entire substrate base 110 included in the package substrate 100. For example, the substrate base 110, the at least one substrate base 110, or the plurality of substrate bases 110 refers to one substrate base 110 when the package substrate 100 includes one substrate base 110, and a structure in which two or more substrate bases 110 are stacked when the package substrate 100 includes the two or more stacked substrate bases 110. An upper surface and a lower surface of the substrate base 110, an upper surface and a lower surface of the at least one substrate base 110, or upper surfaces and lower surfaces of the plurality of substrate bases 110 refer to upper surfaces and lower surfaces of all the substrate bases 110 included in the package substrate 100. For example, the upper surface and the lower surface of the substrate base 110, the upper surface and the lower surface of the at least one substrate base 110, or the upper surfaces and the lower surfaces of the plurality of substrate bases 110 refer to an upper surface and a lower surface of one substrate base 110 when the package substrate 100 includes one substrate base 110, and an upper surface and a lower surface of a structure in which two or more substrate bases 110 are stacked when the package substrate 100 includes the two or more stacked substrate bases 110.

The substrate wiring structure 120 may include a plurality of substrate wiring patterns 122 disposed on the upper surface and the lower surface of the substrate base 110 or disposed inside the substrate base 110 and extending in a horizontal direction and a plurality of substrate via patterns 124 penetrating at least apart of the substrate base 110 and extending in a vertical direction (Z direction) to electrically connect between two substrate wiring patterns 122 located at different vertical levels among the plurality of substrate wiring patterns 122. In some embodiments, the package substrate 100 may include the plurality of stacked substrate bases 110, and the plurality of substrate wiring patterns 122 may be respectively disposed on upper surfaces and lower surfaces of the plurality of substrate bases 110. For example, some of the plurality of substrate wiring patterns 122 may be disposed between two substrate bases 110 adjacent to each other in the vertical direction (Z direction) among the plurality of substrate bases 110.

The substrate wiring structure 120 may include copper (Cu) or an alloy including copper (Cu). Each of the plurality of substrate wiring patterns 122 may include an electrically depressed (ED) copper foil, a rolled-annealed (RA) copper foil, ultra-thin copper foils, sputtered copper, copper alloys, etc. Each of the plurality of substrate via patterns 124 may be formed to fill at least a part of a via through hole penetrating at least a part of the substrate base 110. For example, the substrate via pattern 124 may include copper, nickel, stainless steel, or beryllium copper. In some embodiments, the substrate via pattern 124 may cover an inner wall of the via through hole penetrating the substrate base 110 but may not completely fill the via through hole, and a via filling insulating layer 128 may cover the substrate via pattern 124 and fill the via through hole. For example, the via through hole may be completely filled by the substrate via pattern 124 and the via filling insulating layer 128.

The package substrate 100 may further include a solder resist layer 130 covering the upper surface and the lower surface of the substrate base 110. The solder resist layer 130 may include an upper solder resist layer 132 covering the upper surface of the substrate base 110 and a lower solder resist layer 134 covering the lower surface of the substrate base 110. The upper solder resist layer 132 may have an upper surface 132U and a lower surface 132L. The lower surface 132L of the upper solder resist layer 132 may be in contact with the upper surface of the substrate base 110. The lower solder resist layer 134 may have an upper surface 134U and a lower surface 134L. The upper surface 134U of the lower solder resist layer 134 may be in contact with the lower surface of the substrate base 110. Each of the upper solder resist layer 132 and the lower solder resist layer 134 may have a thickness of about 10 μm to about 15 μm. As one exemplary measurement method of the aforementioned thicknesses, a “thickness” of an element having two opposing surfaces may mean an average value of shortest distances between the two targeted surfaces measured in a direction perpendicular to the targeted surfaces at multiple locations (e.g., 3, 5, or 10) at equal intervals (or non-equal intervals, alternatively). Other methods appreciated by one of ordinary skill in the art, even if not described in the present disclosure, may also be used.

Some of the substrate wiring patterns 122 disposed on the upper surface of the substrate base 110 may be a plurality of upper surface connection pads 122UP. For example, some of the uppermost substrate wiring patterns 122 located at the highest vertical level may be the plurality of upper surface connection pads 122UP. The upper solder resist layer 132 may cover side surfaces of the substrate wiring patterns 122 disposed on the upper surface of the substrate base 110. Some of the substrate wiring patterns 122 disposed on the upper surface of the substrate base 110 may not be completely covered by the upper solder resist layer 132. In some embodiments, the upper solder resist layer 132 may not cover at least a part of upper surfaces of the plurality of upper surface connection pads 122UP. For example, the upper solder resist layer 132 may cover a part of the upper surface adjacent to side surfaces of each of the upper surface connection pads 122UP among the plurality of substrate wiring patterns 122, but may not cover the remaining part of the upper surface. Among the substrate wiring patterns 122 disposed on the upper surface of the substrate base 110, the substrate wiring patterns 122 including at least a part of the upper surfaces not covered by the upper solder resist layer 132 may be the plurality of upper surface connection pads 122UP. A plurality of bonding wires 600 may be respectively connected to the plurality of upper surface connection pads 122UP.

Some of the substrate wiring patterns 122 disposed on the lower surface of the substrate base 110 may be a plurality of lower surface connection pads 122LP. For example, some of the lowermost substrate wiring patterns 122 located at the lowest vertical level may be the plurality of lower surface connection pads 122LP. The lower solder resist layer 134 may cover side surfaces of the substrate wiring patterns 122 disposed on the lower surface of the substrate base 110. Some of the substrate wiring patterns 122 disposed on the lower surface of the substrate base 110 may not be completely covered by the lower solder resist layer 134. In some embodiments, the lower solder resist layer 134 may not cover at least a part of lower surfaces of the plurality of lower surface connection pads 122LP. For example, the lower solder resist layer 134 may cover a part of the lower surface adjacent to the side surfaces of each of the plurality of lower surface connection pads 122LP among the plurality of substrate wiring patterns 122, but may not cover the remaining part of the lower surface, and the substrate wiring patterns 122 having at least a part of the lower surfaces not covered by the lower solder resist layer 134 may be the plurality of lower surface connection pads 122LP. The plurality of upper surface connection pads 122UP and the plurality of lower surface connection pads 122LP respectively corresponding to each other may be electrically connected to the plurality of substrate wiring patterns 122 through the plurality of substrate via patterns 124.

A plurality of package connection terminals 150 may be attached onto the lower surface of the package substrate 100. The plurality of package connection terminals 150 may be respectively attached onto the plurality of lower surface connection pads 122LP. The plurality of package connection terminals 150 may be electrically connected to the semiconductor chip 200 through the substrate wiring structure 120. In some embodiments, the plurality of package connection terminals 150 may completely cover the surfaces of the plurality of lower surface connection pads 122LP not covered by the lower solder resist layer 134, for example, at least a part of the lower surfaces. A horizontal width WT of the package connection terminal 150 may be about 80 μm or more. For example, the horizontal width WT of the package connection terminal 150 may be about 80 μm to about 250 μm. In some embodiments, the horizontal width WT of the package connection terminal 150 may be about 100 μm to about 180 μm.

Alternatively, among conductive material layers disposed on the upper surface of the substrate base 110, parts not covered by the upper solder resist layer 132 may be referred to as the plurality of upper surface connection pads 122UP, only a part connected to the plurality of upper surface connection pads 122UP and covered by the upper solder resist layer 132 may be referred to as the uppermost substrate wiring pattern 122 among the plurality of substrate wiring patterns 122, among conductive material layers disposed on the lower surface of the substrate base 110, parts not covered by the lower solder resist layer 134 may be referred to as the plurality of lower surface connection pads 122LP, and only a part connected to the plurality of lower surface connection pads 122LP and covered by the lower solder resist layer 134 may be referred to as the lowermost substrate wiring pattern 122 among the plurality of substrate wiring patterns 122. The substrate wiring structure 120 including the plurality of substrate wiring patterns 122 and the plurality of substrate via patterns 124 may electrically connect the plurality of upper surface connection pads 122UP to the plurality of lower surface connection pads 122LP.

In a plan view, the package substrate 100 may have a rectangular shape extending in each of a first horizontal direction (X direction) and a second horizontal direction (Y direction). The first horizontal direction (X direction) and the second horizontal direction (Y direction) may be orthogonal to each other. In some embodiments, the extension length of the package substrate 100 in the second horizontal direction (Y direction) may be longer than the extension length in the first horizontal direction (X direction). For example, the first horizontal direction (X direction) may be a short axis direction of the package substrate 100, and the second horizontal direction (Y direction) may be a long axis direction of the package substrate 100. In a plan view, the package substrate 100 may have a connection region BR to which the plurality of package connection terminals 150 are attached, an edge region ER extending along the edge of the package substrate 100 and spaced apart from the connection region BR, and a middle region MR disposed between the connection region BR and the edge region ER. The connection region BR may be a footprint occupied by the plurality of package connection terminals 150 in a plan view. For example, the connection region BR may be a virtual region having a rectangle in which all of the plurality of package connection terminals 150 are disposed or a rectangle with rounded corners in a plan view. The connection region BR refers to a region spaced apart from the edge region ER and in which the plurality of package connection terminals 150 are disposed, and the middle region MR refers to a region located between the edge region ER and the connection region BR to be spaced apart from the edge of the package substrate 100 and in which the plurality of package connection terminals 150 are not disposed. In a plan view, the middle region MR may surround the connection region BR. For example, in a plan view, the middle region MR may extend continuously along the edge of the connection region BR to completely surround the connection region BR. In a plan view, the edge region ER may surround the middle region MR. For example, in a plan view, the edge region ER may extend continuously along the edge of the middle region MR to completely surround the connection region BR.

The lower surface 134L of the lower solder resist layer 134 may include a first lower surface region 134LH and a second lower surface region 134LL. An arithmetic average roughness Ra of the first lower surface region 134LH may be greater than the arithmetic average roughness Ra of the second lower surface region 134LL. For example, the arithmetic average roughness Ra of the first lower surface region 134LH may be at least twice greater than the arithmetic average roughness Ra of the second lower surface region 134LL. In some embodiments, the arithmetic average roughness Ra of the second lower surface region 134LL may be 50 nm or less, and the arithmetic average roughness Ra of the first lower surface region 134LH may be at least 60 nm greater than the arithmetic average roughness Ra of the second lower surface region 134LL. The arithmetic average roughness Ra is the absolute value of roughness with respect to a reference length, and is the average deviation of each point height of the surface from an average height. Each of the arithmetic average roughness Ra of the second lower surface region 134LL and the arithmetic average roughness Ra of the first lower surface region 134LH does not consider the bending of the lower solder resist layer 134 caused by transfer of the substrate wiring structure 120 including the plurality of substrate wiring patterns 122. For example, each of the arithmetic average roughness Ra of the second lower surface region 134LL and the arithmetic average roughness Ra of the first lower surface region 134LH may be obtained only for a part of the lower solder resist layer 134 in direct contact with the lower surface of the substrate base 110.

The connection region BR and the middle region MR may be the second lower surface region 134LL, and at least a part of the edge region ER may be the first lower surface region 134LH. For example, the arithmetic average roughness Ra of at least a part of the edge region ER may be greater than the arithmetic average roughness Ra of each of the connection region BR and the middle region MR. The first lower surface region 134LH may be located only in the edge region ER. In some embodiments, the second lower surface region 134LL may be located only in the connection region BR and the middle region MR. For example, the edge region ER may be entirely the first lower surface region 134LH, and each of the connection region BR and the middle region MR may be entirely the second lower surface region 134LL. The first lower surface region 134LH may surround the second lower surface region 134LL. For example, in a plan view, the first lower surface region 134LH may extend continuously along the edge of the second lower surface region 134LL to completely surround the second lower surface region 134LL. In some embodiments, in a plan view, the first lower surface region 134LH may have a rectangular ring shape.

A first length L1, which is the shortest distance between the edge of the package substrate 100 and the plurality of package connection terminals 150 in the second horizontal direction (Y direction), may be less than a second length L2, which is the shortest distance between the edge of the package substrate 100 and the plurality of package connection terminals 150 in the first horizontal direction (X direction). The edge region ER may have a third length L3 that is a horizontal width in the second horizontal direction (Y direction) and a fourth length L4 that is a horizontal width in the first horizontal direction (X direction). In some embodiments, the third length L3 may be greater than or equal to ½ of the first length L1 and less than the first length L1. A fifth length L5, which is the shortest distance between the edge region ER and the plurality of package connection terminals 150 in the second horizontal direction (Y direction), may be the difference between the first length L1 and the third length L3. In some embodiments, the fifth length L5 may be less than ½ of the first length L1 and may be greater than or equal to the horizontal width WT of the package connection terminal 150. For example, the third length L3 may be greater than or equal to ½ of the first length L1 and less than or equal to ¾ of the first length L1. A sixth length L6, which is the shortest distance between the edge region ER and the plurality of package connection terminals 150 in the first horizontal direction (X direction), may be the difference between the second length L2 and the fourth length L4. The fourth length L4 may be less than each of the third length L3 and the sixth length L6. In some embodiments, the sixth length L6 may be the same as or similar to the fifth length L5. For example, the sixth length L6 may be less than ½ of the first length L1 and may be greater than or equal to the horizontal width WT of the package connection terminal 150.

The semiconductor chip 200 may be attached onto the package substrate 100. The semiconductor chip 200 may include a semiconductor substrate 210. The semiconductor substrate 210 may include a semiconductor material such as a group IV semiconductor material, a group III-V semiconductor material, a group II-VI semiconductor material, and a group II-VI oxide semiconductor material. For example, the semiconductor substrate 210 may include silicon (Si). Alternatively, the semiconductor substrate 210 may include a semiconductor element such as germanium (Ge), or a compound semiconductor such as silicon carbide (SiC), gallium arsenide (GaAs), indium arsenide (InAs), and indium phosphide (InP). Alternatively, the semiconductor substrate 210 may have a silicon-on-insulator (SOI) structure. For example, the semiconductor substrate 210 may include a buried oxide layer (BOX). The semiconductor substrate 210 may include a conductive region, for example, a well doped with impurities. The semiconductor substrate 210 may have various device isolation structures such as a shallow trench isolation (STI) structure. The semiconductor substrate 210 may have an active surface and an inactive surface opposite to the active surface.

A semiconductor device 205 including a plurality of individual devices of various types may be formed on the active surface of the semiconductor chip 200. The plurality of individual devices may include various microelectronic devices, such as a metal-oxide-semiconductor field effect transistor (MOSFET), such as a complementary metal-insulator-semiconductor transistor (CMOS) transistor, an image sensor such as a system large scale integration (LSI), and a CMOS imaging sensor (CIS), a micro-electro-mechanical system (MEMS), an active device, a passive device, etc. The plurality of individual devices may be electrically connected to the conductive region of the semiconductor substrate 210. The semiconductor device 205 may further include or a conductive wiring or a conductive plug electrically connecting at least two of the plurality of individual devices, or the plurality of individual devices to the conductive region of the semiconductor substrate 210. In addition, each of the plurality of individual devices may be electrically separated from other adjacent individual devices by an insulating layer.

The semiconductor device 205 may be a logic semiconductor device or a memory semiconductor device. In some embodiments, the semiconductor chip 200 may be a non-memory semiconductor chip. For example, the semiconductor chip 200 may be a central processing unit (CPU) chip, a graphics processing unit (GPU) chip, or an application processor (AP) chip. In some embodiments, the semiconductor chip 200 may be a memory semiconductor chip. For example, the semiconductor device 205 may be a nonvolatile memory semiconductor device such as flash memory, phase-change random access memory (PRAM), magnetoresistive random access memory (MRAM), ferroelectric random access memory (FeRAM), or resistive random access memory (RRAM). The flash memory may be, for example, a V-NAND flash memory. In some embodiments, the semiconductor chip 200 may be a volatile memory semiconductor chip. For example, the semiconductor device 205 may be a volatile memory semiconductor device such as dynamic random access memory (DRAM) or static random access memory (SRAM).

The semiconductor chip 200 may include a plurality of chip pads 230 disposed on the upper surface of the semiconductor chip 200. For example, the plurality of chip pads 230 may be disposed on the active surface of the semiconductor substrate 210. The semiconductor chip 200 may be stacked on the package substrate 100 such that the active surface faces upward, i.e., in an opposite direction to the package substrate 100. The semiconductor chip 200 may be stacked on the package substrate 100 such that the inactive surface of the semiconductor substrate 210 faces downward, that is, the package substrate 100. The plurality of bonding wires 600 may be connected between the plurality of chip pads 230 and the plurality of upper surface connection pads 122UP. The semiconductor chip 200 may be electrically connected to the package substrate 100 through the plurality of bonding wires 600.

The semiconductor chip 200 may have a die adhesive film 280 attached onto the lower surface thereof, that is, the inactive surface of the semiconductor substrate 210, therebetween and be attached on the package substrate 100. The die adhesive film 280 may include, for example, an inorganic adhesive or a polymer adhesive. The polymer adhesive may include, for example, a thermosetting polymer or a thermoplastic polymer. The thermosetting polymer has a three-dimensional cross-link structure after a monomer is heat-molded and does not soften even when reheated. In contrast, the thermoplastic polymer, which is a polymer exhibiting plasticity by heating, has a linear polymer structure. In addition, the polymer adhesive may be formed in a hybrid type by mixing these two components.

The molding layer 700 covering the upper surface of the package substrate 100 and surrounding the semiconductor chip 200 and the plurality of bonding wires 600 may be disposed on the package substrate 100. The molding layer 700 may be, for example, a molding member including an epoxy mold compound (EMC).

The electromagnetic wave shielding layer 900 may cover side surfaces of the package substrate 100 and side surfaces and an upper surface of the molding layer 700. For example, the electromagnetic wave shielding layer 900 may integrally cover the side surfaces of the package substrate 100 and the side surfaces and the upper surface of the molding layer 700. In some embodiments, the electromagnetic wave shielding layer 900 may be formed in a conformal shielding manner. For example, the electromagnetic wave shielding layer 900 may be generally formed to have a constant thickness to conformally cover the side surfaces of the package substrate 100 and the side surfaces and the upper surface of the molding layer 700. The electromagnetic wave shielding layer 900 may shield electromagnetic waves emitted from the semiconductor chip 200 and electromagnetic waves emitted from the side surfaces of the package substrate 100. In some embodiments, the electromagnetic wave shielding layer 900 may be connected to the substrate wiring pattern 122 to which the ground is provided among the plurality of substrate wiring patterns 122. For example, at least one of the plurality of substrate wiring patterns 122 may be exposed to the side surfaces of the package substrate 100 and the ground may be provided.

In some embodiments, the electromagnetic wave shielding layer 900 may cover all side surfaces of the package substrate 100 but may not cover the lower surface thereof. For example, the electromagnetic wave shielding layer 900 may cover all side surfaces of the substrate base 110, the upper solder resist layer 132, and the lower solder resist layer 134. In some embodiments, the lowermost end of the electromagnetic wave shielding layer 900 may be at the same vertical level as the lower surface of the package substrate 100. For example, the lowermost end of the electromagnetic wave shielding layer 900 may be at the same vertical level as a part of the lower surface of the package substrate 100 on the edge side of the package substrate 100. For example, on the edge side of the package substrate 100, the lowermost end of the lower solder resist layer 134 and the lowermost end of the electromagnetic wave shielding layer 900 may be at the same vertical level.

In some embodiments, the electromagnetic wave shielding layer 900 may be formed by, for example, a physical vapor deposition (PVD) method. For example, the electromagnetic wave shielding layer 900 may be formed by a sputtering process. For example, the electromagnetic wave shielding layer 900 may include copper (Cu) or a metal material such as stainless steel. In some embodiments, the electromagnetic wave shielding layer 900 may have a stack structure in which upper and lower surfaces of a copper layer are covered by a stainless steel layer. In some embodiments, the electromagnetic wave shielding layer 900 may be formed, for example, by a spray method. For example, the electromagnetic wave shielding layer 900 may include a metal material such as silver. In some embodiments, the electromagnetic wave shielding layer 900 may include a metal layer including silver, and a carbon nanotube (CNT) layer disposed between the metal layer and the package substrate 100 and the molding layer 700.

The semiconductor package 1 according to the inventive concept includes the electromagnetic wave shielding layer 900 covering all the upper and side surfaces of the molding layer 700 and the side surfaces of the package substrate 100, thereby preventing the reliability from deteriorating in an electronic device including the semiconductor package 1 due to obstacles such as electromagnetic noise or malfunction caused by the semiconductor package 1.

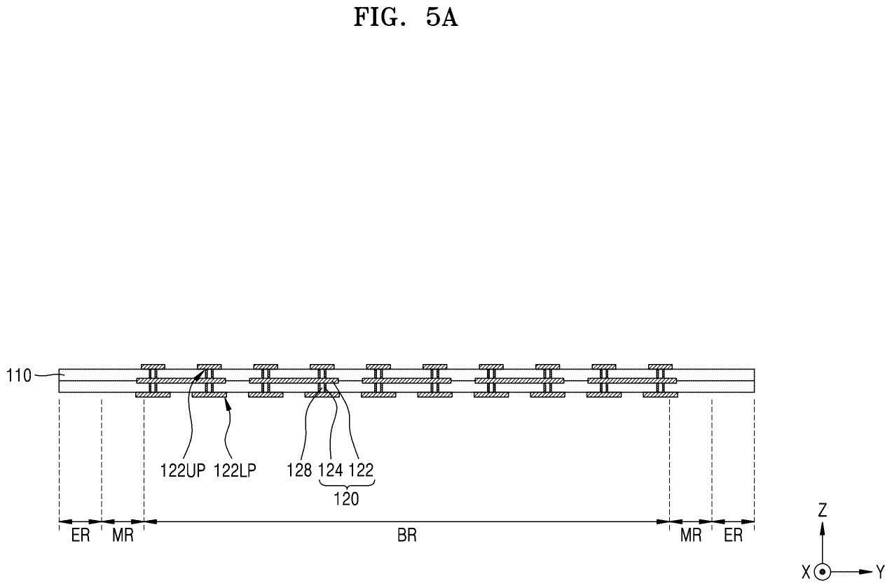

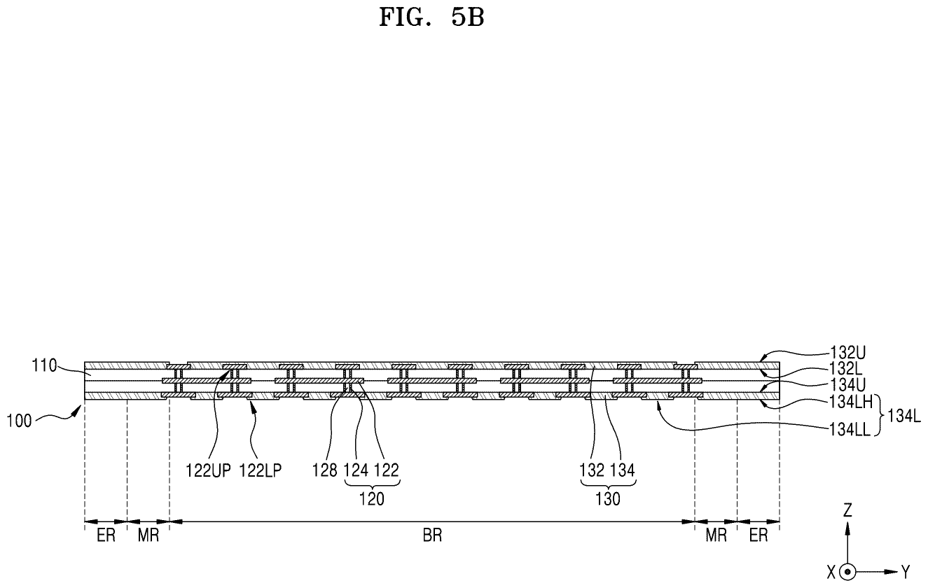

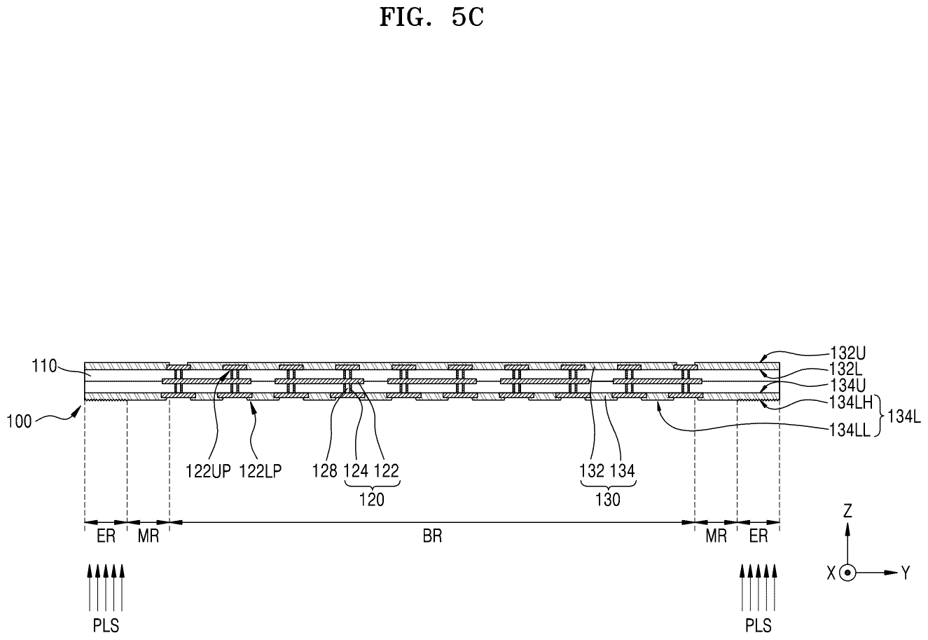

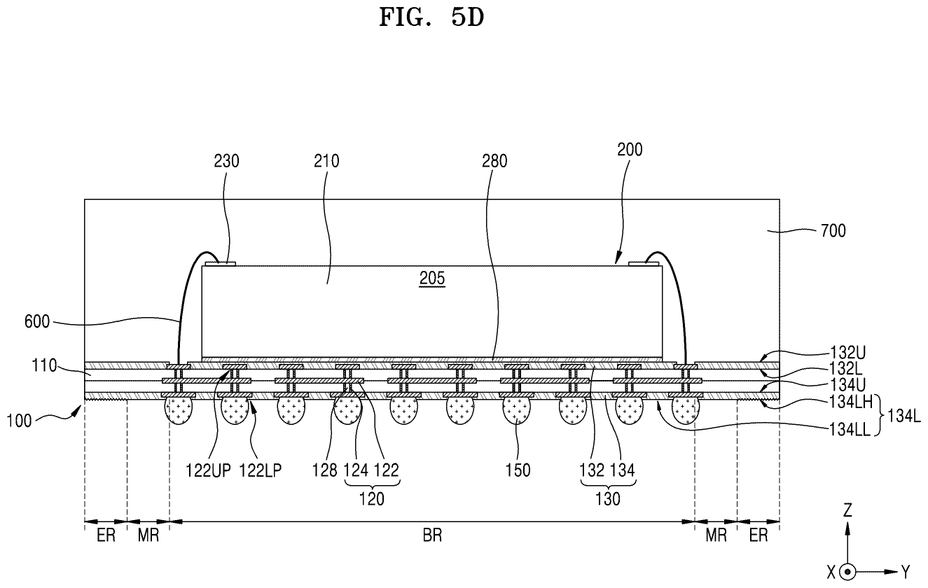

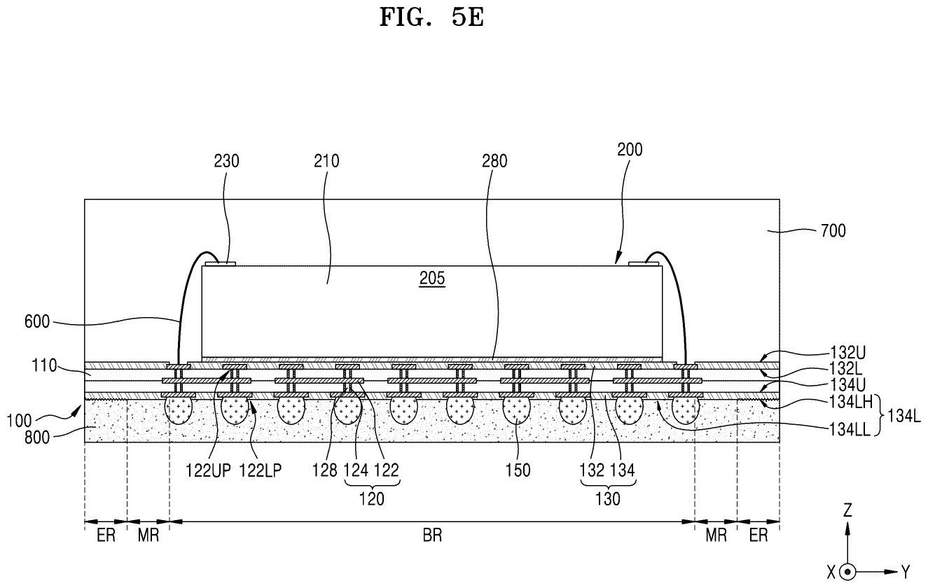

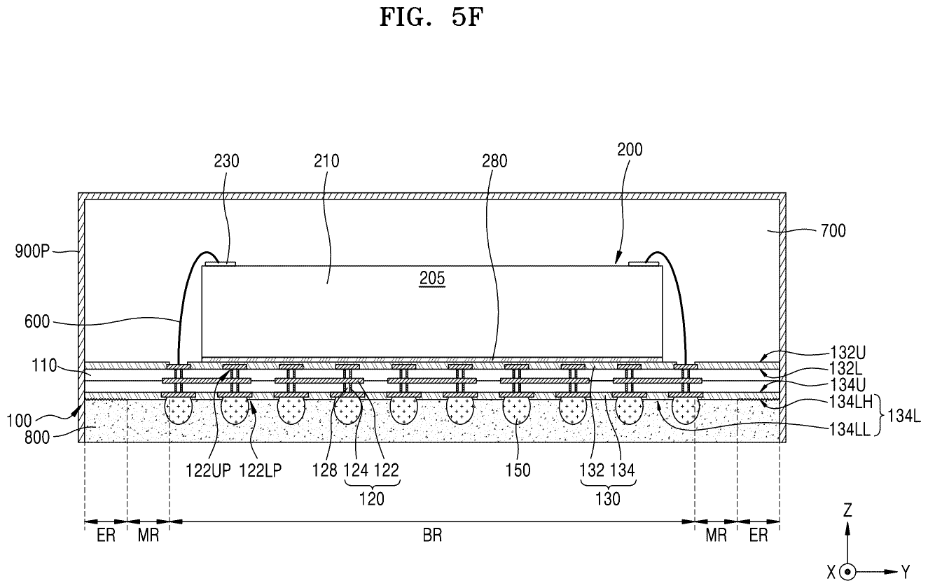

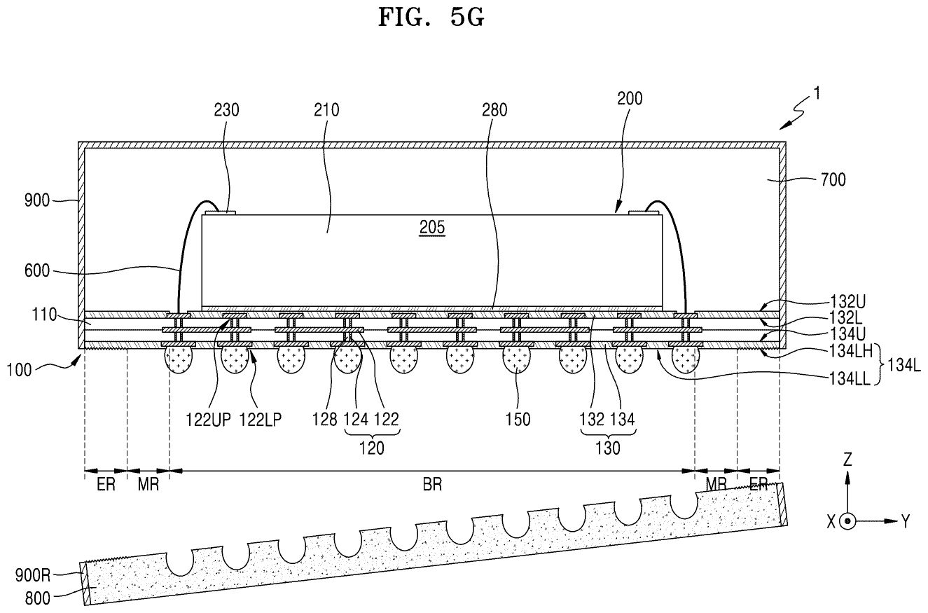

In addition, as will be described with reference to FIGS. 5A to 5G, the package substrate 100 included in the semiconductor package 1 according to the inventive concept has the first lower surface region 134LH with the large arithmetic average roughness Ra in the edge region ER of the lower surface 134L of the lower solder resist layer 134, and thus the electromagnetic wave shielding layer 900 may not extend onto the lower surface 134L of the lower solder resist layer 134, which prevents the occurrence of an electrical short in the plurality of package connection terminals 150, thereby securing the operational reliability of the semiconductor package 1.

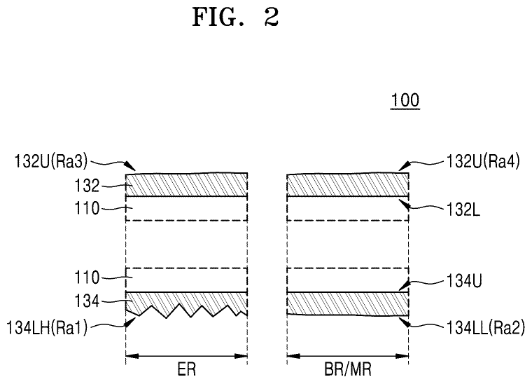

FIG. 2 is a cross-sectional view illustrating parts of a package substrate included in a semiconductor package according to embodiments.

Referring to FIG. 2, the package substrate 100 may include the substrate base 110, the upper solder resist layer 132 covering an upper surface of the substrate base 110, and the lower solder resist layer 134 covering a lower surface of the substrate base 110. The package substrate 100 may have the connection region BR located inside the package substrate 100, the edge region ER extending along the edge of the package substrate 100 and spaced apart from the connection region BR, and the middle region MR disposed between the connection region BR and the edge region ER in a plan view.

The lower surface 134L of the lower solder resist layer 134 may include the first lower surface region 134LH and the second lower surface region 134LL. The connection region BR and the middle region MR may be the second lower surface region 134LL, and at least a part of the edge region ER may be the first lower surface region 134LH. A first arithmetic average roughness Ra1, which is the arithmetic average roughness Ra of the first lower surface region 134LH, may be greater than a second arithmetic average roughness Ra2, which is the arithmetic average roughness Ra of the second lower surface region 134LL. For example, the first arithmetic average roughness Ra1 may be at least twice greater than the second arithmetic average roughness Ra2. In some embodiments, the first arithmetic average roughness Ra1 may be at least 60 nm greater than the second arithmetic average roughness Ra2, and the second arithmetic average roughness Ra2 may be 50 nm or less. In some embodiments, the edge region ER may all be the first lower surface region 134LH, and each of the connection region BR and the middle region MR may be the second lower surface region 134LL. For example, the edge region ER may have the first arithmetic average roughness Ra1, and each of the connection region BR and the middle region MR may have the second arithmetic average roughness Ra2.

The upper surface 132U of the upper solder resist layer 132 may have a third arithmetic average roughness Ra3 in the edge region ER, and may have a fourth arithmetic average roughness Ra4 in the connection region BR and the middle region MR. Each of the third arithmetic average roughness Ra3 and the fourth arithmetic average roughness Ra4 may be less than the first arithmetic average roughness Ra1.

For example, the first arithmetic average roughness Ra1 may be at least twice greater than each of the third arithmetic average roughness Ra3 and the fourth arithmetic average roughness Ra4. In some embodiments, the first arithmetic average roughness Ra1 may be at least 60 nm greater than each of the third arithmetic average roughness Ra3 and the fourth arithmetic average roughness Ra4, and each of the third arithmetic average roughness Ra3 and the fourth arithmetic average roughness Ra4 may be 50 nm or less. In some embodiments, the second arithmetic average roughness Ra2, the third arithmetic average roughness Ra3, and the fourth arithmetic average roughness Ra4 may be substantially the same. As used herein, the expression “substantially the same” may refer to having the same value relative to other value(s) compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

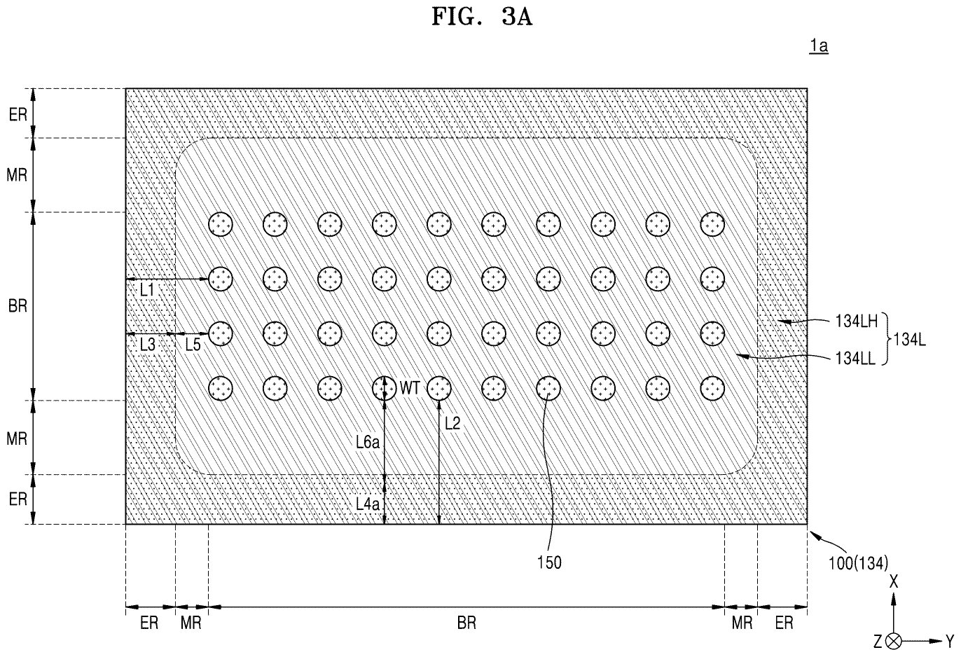

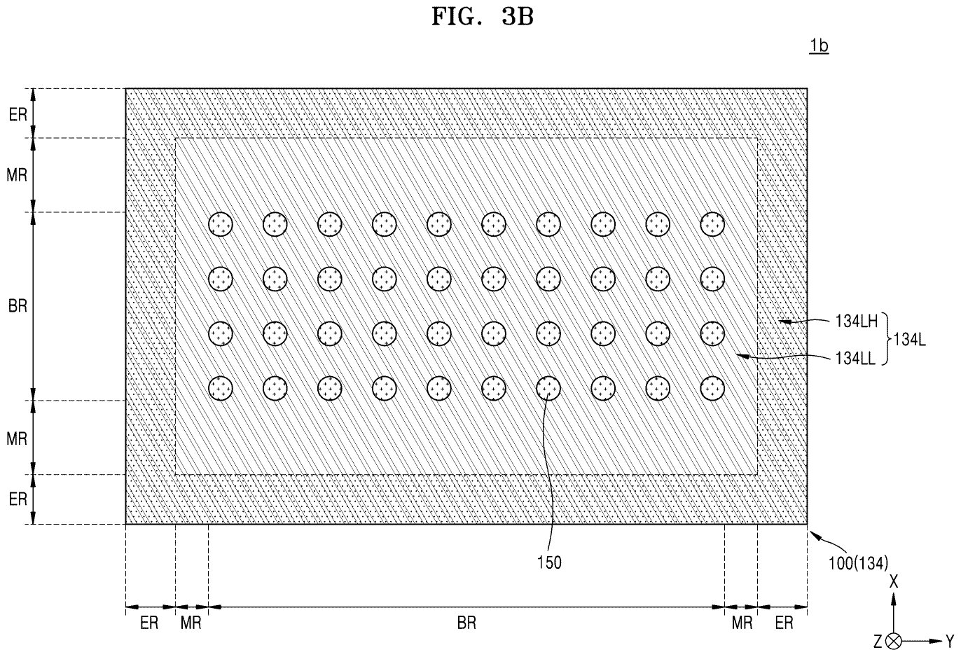

FIGS. 3A and 3B are plan views illustrating lower surfaces of semiconductor packages according to embodiments.

Referring to FIG. 3A, a semiconductor package 1a may include the package substrate 100. The package substrate 100 may include the lower solder resist layer 134. The package substrate 100 may have the connection region BR located inside the package substrate 100, the edge region ER extending along the edge of the package substrate 100 and spaced apart from the connection region BR, and the middle region MR disposed between the connection region BR and the edge region ER in a plan view. The connection region BR may be a virtual region having a rectangle with rounded corners in which all of the plurality of package connection terminals 150 are disposed in a plan view. Both the connection region BR and the middle region MR may be the second lower surface region 134LL, and the edge region ER may be the first lower surface region 134LH.

The first length L1, which is the shortest distance between the edge of the package substrate 100 and the plurality of package connection terminals 150 in the second horizontal direction (Y direction), may be less than the second length L2, which is the shortest distance between the edge of the package substrate 100 and the plurality of package connection terminals 150 in the first horizontal direction (X direction). The edge region ER may have a third length L3 that is a horizontal width in the second horizontal direction (Y direction) and a fourth length L4a that is a horizontal width in the first horizontal direction (X direction). A sixth length L6a, which is the shortest distance between the edge region ER and the plurality of package connection terminals 150 in the first horizontal direction (X direction), may be the difference between the second length L2 and the fourth length L4a. In some embodiments, the fourth length L4a may be the same as or similar to the third length L3. The sixth length L6a may be greater than each of the fourth length L4a and the fifth length L5.

Referring to FIG. 3B, a semiconductor package 1b may include the package substrate 100. The package substrate 100 may include the lower solder resist layer 134. The package substrate 100 may have the connection region BR located inside the package substrate 100, the edge region ER extending along the edge of the package substrate 100 and spaced apart from the connection region BR, and the middle region MR disposed between the connection region BR and the edge region ER in a plan view. The connection region BR may be a virtual region having a rectangle in which all of the plurality of package connection terminals 150 are disposed in a plan view.

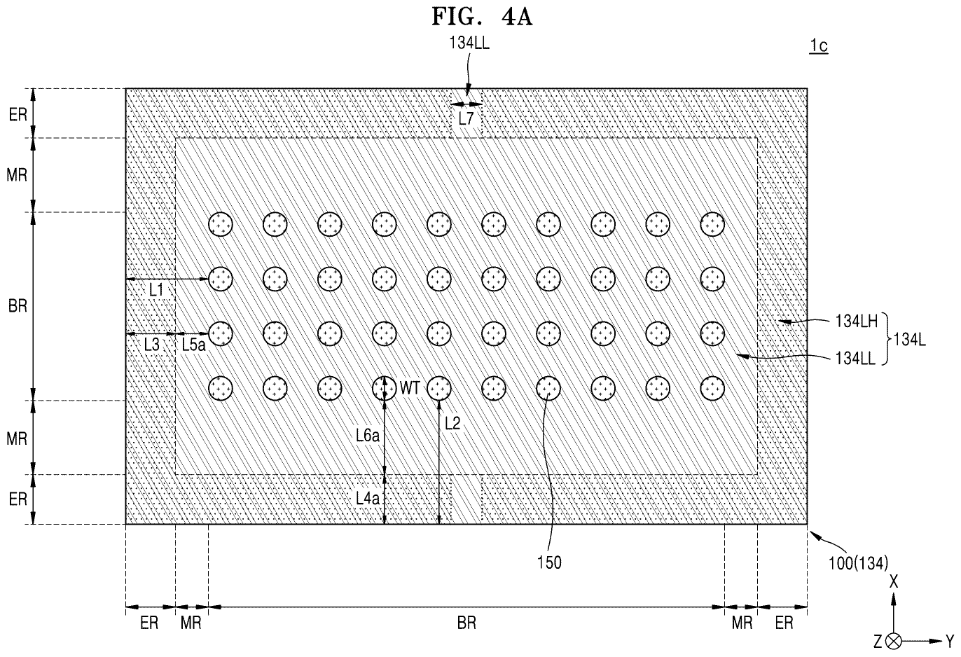

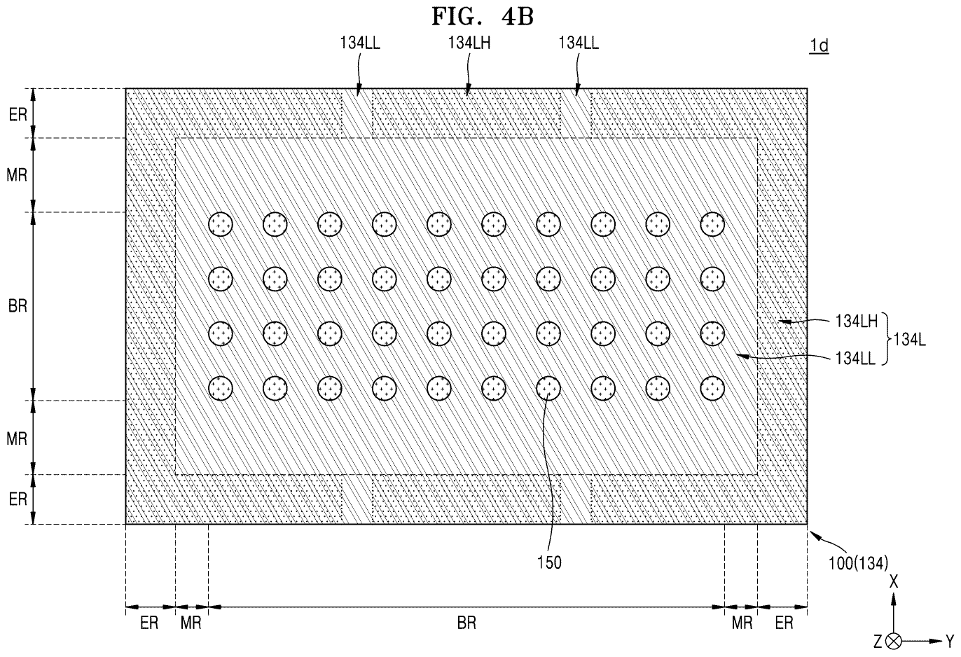

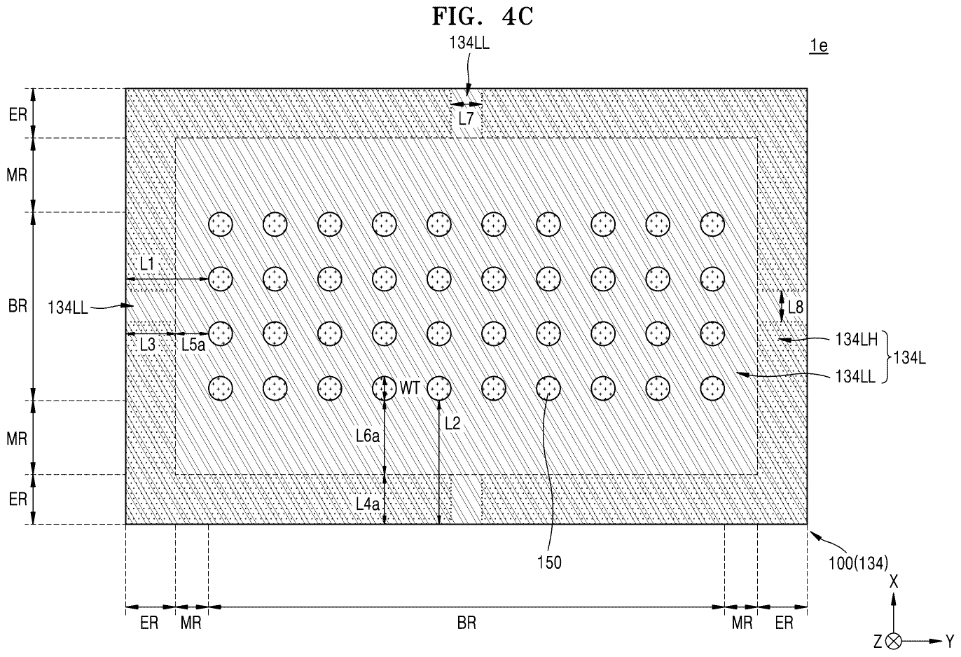

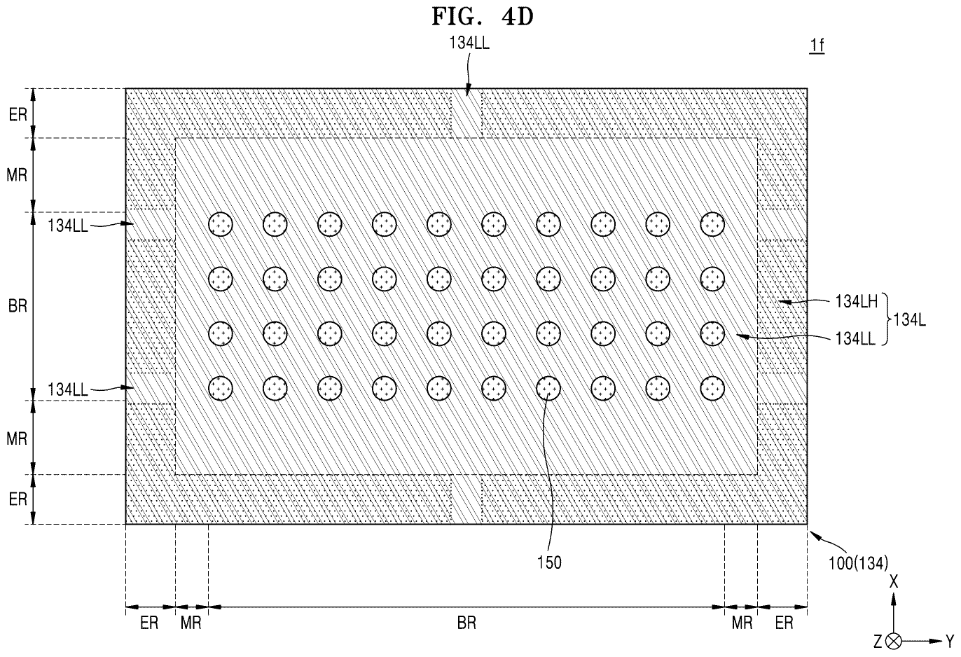

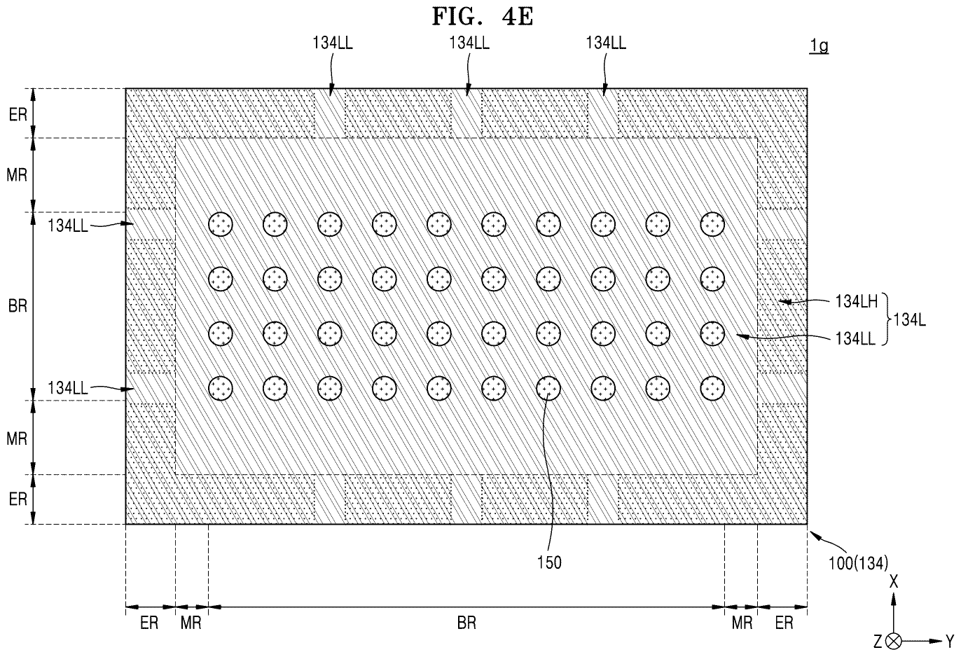

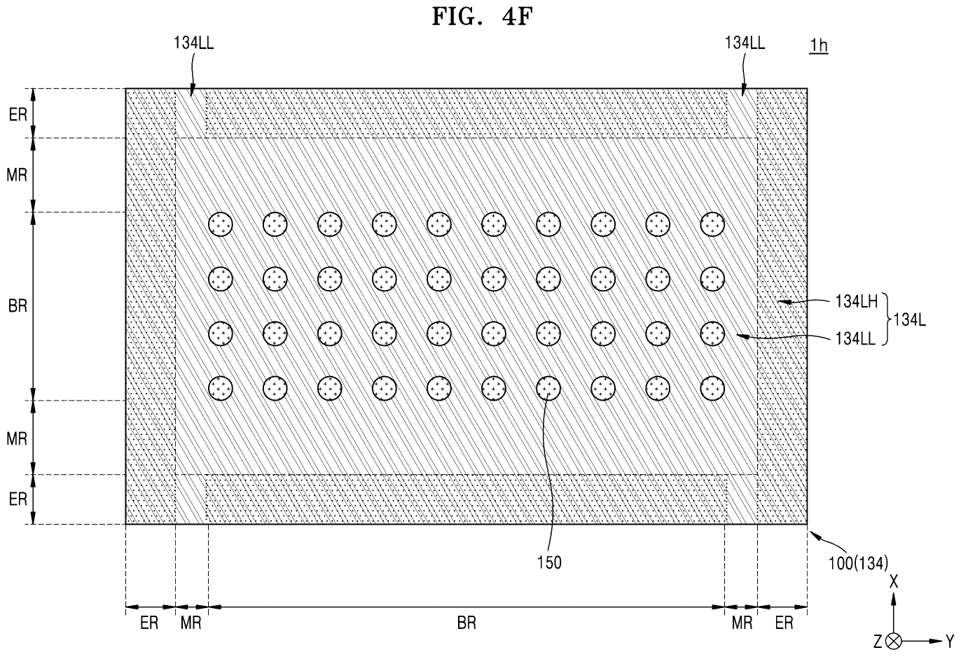

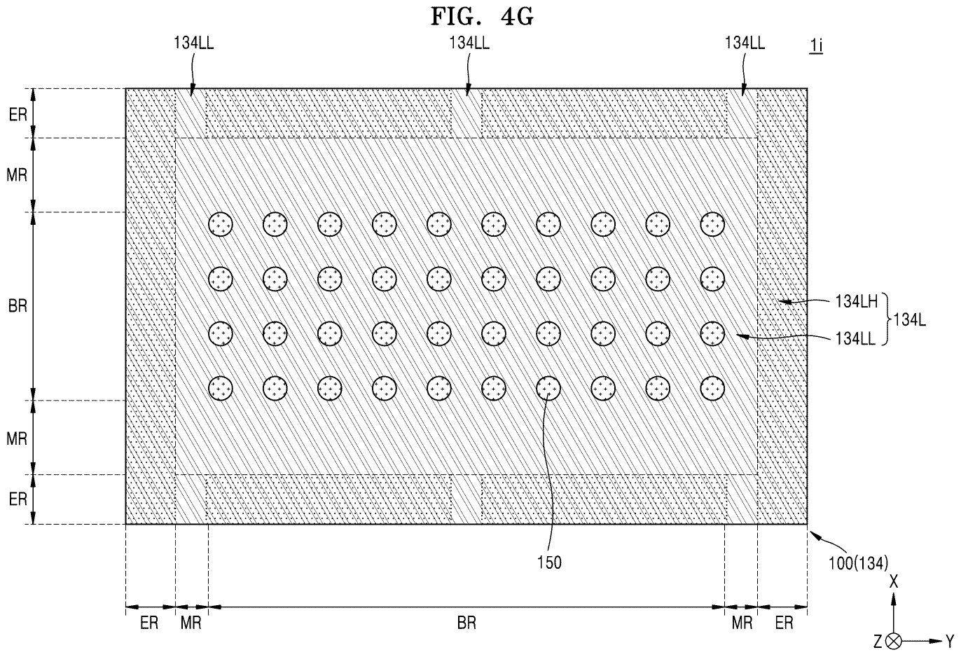

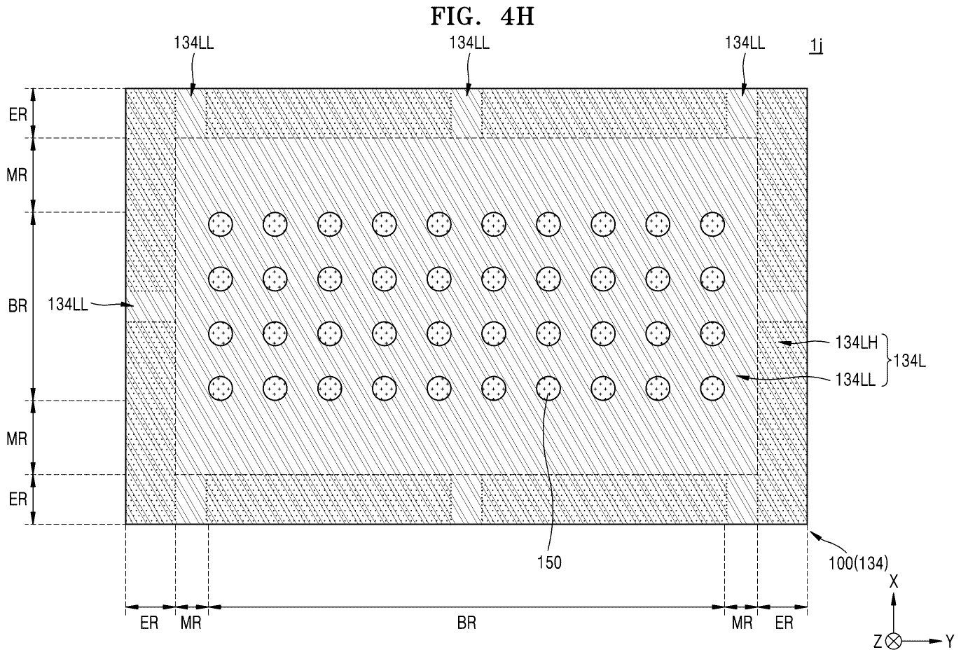

FIGS. 4A to 4H are plan views illustrating lower surfaces of semiconductor packages according to embodiments.

Referring to FIG. 4A, a semiconductor package 1c may include the package substrate 100. The package substrate 100 may include the lower solder resist layer 134. Both the connection region BR and the middle region MR may be the second lower surface region 134LL, a part of the edge region ER may be the first lower surface region 134LH, and the other part of the edge region ER may be the second lower surface region 134LL. For example, the edge region ER may have two first lower surface regions 134LH spaced apart from each other. In a plan view, each of the two first lower surface regions 134LH may have a U shape. For example, in a plan view, the two first lower surface regions 134LH may be disposed such that U-shaped open parts face each other. The second lower surface regions 134LL may be disposed between the two first lower surface regions 134LH. The two first lower surface regions 134LH may have a gap of a seventh length L7 and may be spaced apart from each other. For example, each of the second lower surface regions 134LL may have a horizontal width of the seventh length L7 in the second horizontal direction (Y direction). The seventh length L7 may be less than each of the third length L3 and the fourth length L4a. That is, the gap between the two first lower surface regions 134LH may be less than the horizontal width of the first lower surface region 134LH in an inward direction from the edge of the package substrate 100.

Referring to FIG. 4B, a semiconductor package 1d may include the package substrate 100. The package substrate 100 may include the lower solder resist layer 134. Both the connection region BR and the middle region MR may be the second lower surface region 134LL, a part of the edge region ER may be the first lower surface region 134LH, and the other part of the edge region ER may be the second lower surface region 134LL. For example, the edge region ER may have the plurality of first lower surface regions 134LH spaced apart from each other. In a plan view, each of two of the plurality of first lower surface regions 134LH may have a U-shape, and each of the other first lower surface regions 134LH may have an I-shape. For example, in a plan view, the two first lower surface regions 134LH having the U-shape may be disposed so that U-shaped open parts face each other, and the first lower surface regions 134LH having the I-shape may be disposed between the two first lower surface regions 134LH having the U-shape.

In FIG. 4B, one first lower surface region 134LH having the I-shape is disposed along each of two edges of the package substrate 100 extending in the second horizontal direction (Y direction), and the two second lower surface regions 134LL are disposed at both ends of one first lower surface region 134LH having the I-shape in the second horizontal direction (Y direction), but the embodiments are not limited thereto. For example, two or more first lower surface regions 134LH having the I-shape and three or more second lower surface regions 134LL may be alternately disposed along each of the two edges of the package substrate 100 extending in the second horizontal direction (Y direction).

Referring to FIG. 4C, a semiconductor package 1e may include the package substrate 100. The package substrate 100 may include the lower solder resist layer 134. Both the connection region BR and the middle region MR may be the second lower surface region 134LL, a part of the edge region ER may be the first lower surface region 134LH, and the other part of the edge region ER may be the second lower surface region 134LL. For example, the edge region ER may have four first lower surface regions 134LH spaced apart from each other. In a plan view, each of the four first lower surface regions 134LH may have an L shape. For example, in a plan view, each of the four first lower surface regions 134LH may extend from each of four corners of the package substrate 100 along two edges connected to each of the four corners. The second lower surface regions 134LL may be disposed between the four first lower surface regions 134LH. Two first lower surface regions 134LH adjacent to each other in the second horizontal direction (Y direction) among the four first lower surface regions 134LH may be spaced apart from each other with the gap of the seventh length L7 in the second horizontal direction (Y direction), and two first lower surface regions 134LH adjacent to each other in the first horizontal direction (X direction) among the four first lower surface regions 134LH may be spaced apart from each other with a distance of an eighth length L8 in the first horizontal direction (X direction). The seventh length L7 and the eighth length L8 may be respectively less than the third length L3 and the fourth length L4a. That is, the gap between the four first lower surface regions 134LH may be less than the horizontal width of the first lower surface region 134LH in the inward direction from the edge of the package substrate 100.

Referring to FIG. 4D, a semiconductor package if may include the package substrate 100. The package substrate 100 may include the lower solder resist layer 134. Both the connection region BR and the middle region MR may be the second lower surface region 134LL, a part of the edge region ER may be the first lower surface region 134LH, and the other part of the edge region ER may be the second lower surface region 134LL. For example, the edge region ER may have the plurality of first lower surface regions 134LH spaced apart from each other. In a plan view, each of four of the plurality of first lower surface regions 134LH may have an L-shape, and each of other first lower surface regions 134LH may have an I-shape. In some embodiments, the first lower surface regions 134LH having the I-shape may be disposed between two first lower surface regions 134LH having the L-shape. For example, the first lower surface region 134LH having the I-shape extending along the first horizontal direction (X direction) may be disposed between the two first lower surface regions 134LH having the L-shape adjacent to each other in the first horizontal direction (X direction).

Referring to FIG. 4E, a semiconductor package 1g may include the package substrate 100. The package substrate 100 may include the lower solder resist layer 134. Both the connection region BR and the middle region MR may be the second lower surface region 134LL, a part of the edge region ER may be the first lower surface region 134LH, and the other part of the edge region ER may be the second lower surface region 134LL. For example, the edge region ER may have the plurality of first lower surface regions 134LH spaced apart from each other. In a plan view, each of four of the plurality of first lower surface regions 134LH may have an L-shape, and each other first lower surface regions 134LH may have an I-shape. In some embodiments, the first lower surface regions 134LH having the I-shape may be disposed between two first lower surface regions 134LH having the L-shape. For example, the first lower surface region 134LH having the I-shape extending in the first horizontal direction (X direction) may be disposed between the two first lower surface regions 134LH having the L-shape adjacent to each other in the first horizontal direction (X direction), and the first lower surface region 134LH having the I-shape extending in the second horizontal direction (Y direction) may be disposed between the two first lower surface regions 134LH having the L-shape adjacent to each other in the second horizontal direction (Y direction).

In FIG. 4E, one first lower surface region 134LH having the I-shape is disposed along each of two edges of the package substrate 100 extending in the first horizontal direction (X direction), and two second lower surface regions 134LL having the I-shape spaced apart from each other are disposed along each of two edges of the package substrate 100 extending in the second horizontal direction (Y direction), but the embodiments are not limited thereto. For example, two or more first lower surface regions 134LH having the I-shape spaced apart from each other may be disposed along each of the two edges of the package substrate 100 extending in the first horizontal direction (X direction), and one first lower surface region 134LH having the I-shape or three or more first lower surface regions 134LH having the I-shape spaced apart from each other may be disposed along each of the two edges of the package substrate 100 extending in the second horizontal direction (Y direction).

Referring to FIG. 4F, a semiconductor package 1h may include the package substrate 100. The package substrate 100 may include the lower solder resist layer 134. Both the connection region BR and the middle region MR may be the second lower surface region 134LL, a part of the edge region ER may be the first lower surface region 134LH, and the other part of the edge region ER may be the second lower surface region 134LL. For example, the edge region ER may have four first lower surface regions 134LH spaced apart from each other. In a plan view, each of the four first lower surface regions 134LH may have an I shape. For example, in a plan view, some of the four first lower surface regions 134LH having the I-shape may extend in the first horizontal direction (X direction), and others may extend in the second horizontal direction (Y direction). In some embodiments, one first lower surface region 134LH having the I shape may be disposed along each of the two edges of the package substrate 100 extending in the first horizontal direction (X direction), and one first lower surface region 134LH having the I shape may be disposed along each of the two edges of the package substrate 100 extending in the second horizontal direction (Y direction).

Referring to FIG. 4G, a semiconductor package 1i may include the package substrate 100. The package substrate 100 may include the lower solder resist layer 134. Both the connection region BR and the middle region MR may be the second lower surface region 134LL, a part of the edge region ER may be the first lower surface region 134LH, and the other part of the edge region ER may be the second lower surface region 134LL. For example, the edge region ER may have the plurality of first lower surface regions 134LH spaced apart from each other. In a plan view, each of the plurality of first lower surface regions 134LH may have an I shape. For example, in a plan view, some of the plurality of first lower surface regions 134LH having the I-shape may extend in the first horizontal direction (X direction), and others may extend in the second horizontal direction (Y direction). In some embodiments, one first lower surface region 134LH having the I-shape may be disposed along each of the two edges of the package substrate 100 extending in the first horizontal direction (X direction), and two or more first lower surface regions 134LH having the I-shape may be disposed along each of the two edges of the package substrate 100 extending in the second horizontal direction (Y direction).

Referring to FIG. 4H, a semiconductor package 1j may include the package substrate 100. The package substrate 100 may include the lower solder resist layer 134. Both the connection region BR and the middle region MR may be the second lower surface region 134LL, a part of the edge region ER may be the first lower surface region 134LH, and the other part of the edge region ER may be the second lower surface region 134LL. For example, the edge region ER may have the plurality of first lower surface regions 134LH spaced apart from each other. In a plan view, each of the plurality of first lower surface regions 134LH may have an I shape. For example, in a plan view, some of the plurality of first lower surface regions 134LH having the I-shape may extend in the first horizontal direction (X direction), and others may extend in the second horizontal direction (Y direction). In some embodiments, two or more first lower surface regions 134LH having the I-shape may be disposed along each of the two edges of the package substrate 100 extending in the first horizontal direction (X direction), and two or more first lower surface regions 134LH having the I-shape may be disposed along each of the two edges of the package substrate 100 extending in the second horizontal direction (Y direction).

FIGS. 5A to 5G are cross-sectional views illustrating a method of manufacturing a semiconductor package, according to an embodiment.

Referring to FIG. 5A, the substrate wiring structure 120 including the plurality of substrate wiring patterns 122 disposed on an upper surface and a lower surface of the substrate base 110 or disposed inside the substrate base 110 and extending in a horizontal direction, or the plurality of substrate via patterns 124 penetrating at least a part of the substrate base 110 and extending in a vertical direction to electrically connect two substrate wiring patterns 122 located at different vertical levels among the plurality of substrate wiring patterns 122 is formed.

The plurality of substrate wiring patterns 122 may be formed by attaching a copper foil to the upper surface and/or the lower surface of the substrate base 110 or depositing or plating copper or a copper alloy thereto, forming a conductive layer, and then patterning the conductive layer. Some of the substrate wiring patterns 122 disposed on the upper surface of the substrate base 110 may be the plurality of upper surface connection pads 122UP, and some of the substrate wiring patterns 122 disposed on the lower surface of the substrate base 110 may be the plurality of lower surface connection pads 122LP.

The plurality of substrate via patterns 124 may be formed by forming via through holes penetrating at least a part of the substrate base 110, and then filling at least a part of the via through holes. In some embodiments, the substrate via pattern 124 may be formed to cover an inner wall of the via through hole penetrating the substrate base 110 so as not to completely fill the via through hole, and the via filling insulating layer 128 may be formed to cover the substrate via pattern 124 and fill the via through hole.

Referring to FIG. 5B, the solder resist layer 130 covering the upper surface and the lower surface of the substrate base 110 is formed. The solder resist layer 130 may include the upper solder resist layer 132 covering the upper surface of the substrate base 110 and the lower solder resist layer 134 covering the lower surface of the substrate base 110. The upper solder resist layer 132 may have the upper surface 132U and the lower surface 132L. The upper solder resist layer 132 may be formed such that the lower surface 132L of the upper solder resist layer 132 is in contact with the upper surface of the substrate base 110. The upper solder resist layer 132 may be formed not to cover at least a part of upper surfaces of the plurality of upper surface connection pads 122UP. The lower solder resist layer 134 may have the upper surface 134U and the lower surface 134L. The lower solder resist layer 134 may be formed such that the upper surface 134U of the lower solder resist layer 134 is in contact with the lower surface of the substrate base 110. The lower solder resist layer 134 may be formed not to cover at least a part of lower surfaces of the plurality of lower surface connection pads 122LP.

Referring to FIG. 5C, surface treatment is performed on a part of the lower surface 134L of the lower solder resist layer 134 to form the first lower surface region 134LH. The remaining part of the lower surface 134L of the lower solder resist layer 134, on which surface treatment is not performed, may be the second lower surface region 134LL. In some embodiments, the first lower surface region 134LH may be formed by performing surface treatment with plasma PLS on a part of the lower surface 134L of the lower solder resist layer 134. By surface treatment, the arithmetic average roughness Ra of the first lower surface region 134LH may be greater than the arithmetic average roughness Ra of the second lower surface region 134LL.

Referring to FIG. 5D, after attaching the semiconductor chip 200 to the package substrate 100, the plurality of bonding wires 600 connecting the plurality of chip pads 230 included in the semiconductor chip 200 to the plurality of upper surface connection pads 122UP are formed. The semiconductor chip 200 may have the die adhesive film 280 attached onto a lower surface thereof therebetween and be attached onto the package substrate 100.

Thereafter, the molding layer 700 covering the upper surface of the package substrate 100 and surrounding the semiconductor chip 200 and the plurality of bonding wires 600 is formed, and the plurality of package connection terminals 150 are respectively attached onto the plurality of lower surface connection pads 122LP.

Referring to FIG. 5E, an adhesive layer 800 surrounding the plurality of package connection terminals 150 is formed on the lower surface of the package substrate 100. The adhesive layer 800 may be formed to have a thickness for completely surrounding the plurality of package connection terminals 150. For example, the adhesive layer 800 may have a thickness of about 100 μm to about 300 nm.

An upper surface of the adhesive layer 800 may be in contact with the lower surface 134L of the lower solder resist layer 134. A part of the upper surface of the adhesive layer 800 may be in contact with the first lower surface region 134LH of the lower surface 134L of the lower solder resist layer 134. The first lower surface region 134LH has a relatively large arithmetic average roughness Ra, and thus a part of the upper surface of the adhesive layer 800 in contact with the first lower surface region 134LH may have a relatively large adhesive force to the package substrate 100.

Referring to FIG. 5F, a preliminary shielding layer 900P covering side surfaces of the adhesive layer 800, side surfaces of the package substrate 100, and side surfaces and the upper surface of the molding layer 700 is formed.

The package substrate 100 has the first lower surface region 134LH having the large arithmetic average roughness Ra in the edge region ER of the lower surface 134L of the lower solder resist layer 134, and thus, an adhesive force between the edge region ER of the package substrate 100 and the adhesive layer 800 may be relatively large. Therefore, in a process of forming the preliminary shielding layer 900P, a material constituting the preliminary shielding layer 900P may not penetrate between the lower surface of the package substrate 100 and the adhesive layer 800. Therefore, a backspill in which the preliminary shielding layer 900P extends onto the lower surface 134L of the lower solder resist layer 134 may not occur.

Referring to FIG. 5G, the adhesive layer 800 is separated from the package substrate 100 to form the semiconductor package 1. In a process of separating the adhesive layer 800, a part of the preliminary shielding layer 900P shown in FIG. 5F may be a residual shielding layer 900R remaining on side surfaces of the adhesive layer 800, and a part of the preliminary shielding layer 900P covering the side surfaces of the package substrate 100 and the side surfaces and the upper surface of the molding layer 700 may be the electromagnetic wave shielding layer 900.

The package substrate 100 has the second lower surface region 134LL having the small arithmetic average roughness Ra in each of the connection region BR and the middle region MR of the lower surface 134L of the lower solder resist layer 134, and thus a part of the upper surface of the adhesive layer 800 in contact with the second lower surface region 134LL may have a relatively small adhesive force to the package substrate 100. Therefore, in the process of separating the adhesive layer 800 from the package substrate 100, a part of the adhesive layer 800 may not remain between the plurality of package connection terminals 150, or some of the plurality of package connection terminals 150 may not be separated from the lower surface connection pad 122LP of the package substrate 100.

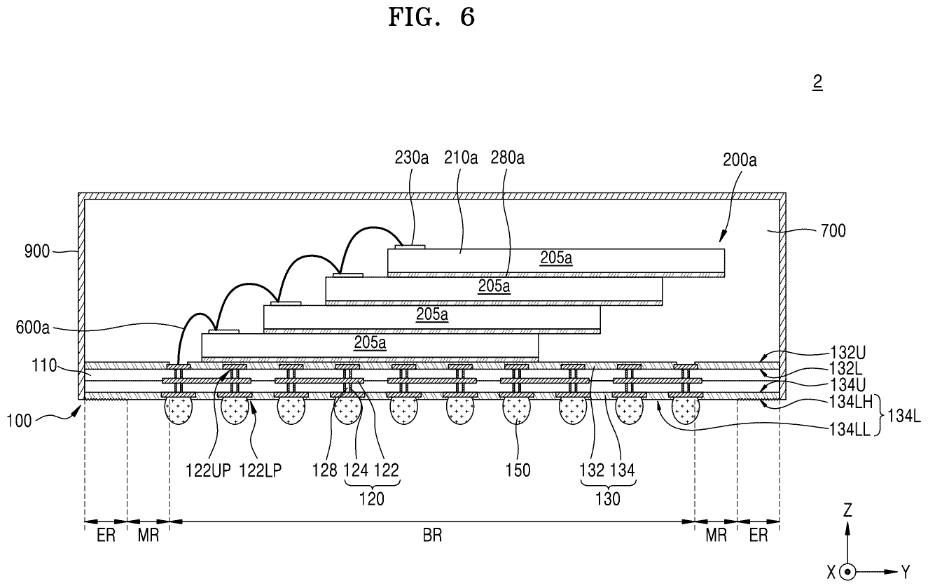

FIG. 6 is a cross-sectional view illustrating a semiconductor package according to embodiments.

Referring to FIG. 6, a semiconductor package 2 includes the package substrate 100, a plurality of semiconductor chips 200a, the molding layer 700, and the electromagnetic wave shielding layer 900. The package substrate 100 includes the solder resist layer 130 covering an upper surface and a lower surface of the substrate base 110. The lower surface 134L of the lower solder resist layer 134 may include the first lower surface region 134LH and the second lower surface region 134LL.

The plurality of semiconductor chips 200a may be sequentially stacked on the package substrate 100 in the vertical direction (Z direction). The plurality of semiconductor chips 200a may be stacked in a step shape with gaps in a horizontal direction. Each of the plurality of semiconductor chips 200a may have a rectangular planar shape. In some embodiments, the plurality of semiconductor chips 200a may be stacked in the step shape with the gaps in a direction of one side of the rectangular planar shape, for example, the second horizontal direction (Y direction) or the first horizontal direction (X direction). In some embodiments, the plurality of semiconductor chips 200a may be stacked at gaps in a diagonal direction of the rectangular planar shape, for example, a diagonal direction between the first horizontal direction (X direction) and the second horizontal direction (Y direction). In some embodiments, some of the plurality of semiconductor chips 200a may be stacked in the step shape with gaps in one direction, and others of the plurality of semiconductor chips 200a may be stacked in the step shape with gaps in an opposite direction to the one direction on some of the plurality of semiconductor chips 200a.

Each of the plurality of semiconductor chips 200a may include a semiconductor device 205a located on an active surface of the semiconductor substrate 210a. The semiconductor device 205a may be a memory semiconductor device. For example, the semiconductor chip 200a may be a memory semiconductor chip. In some embodiments, the semiconductor device 205a may be a flash memory device such as NAND or V-NAND.

Each of the plurality of semiconductor chips 200a may include a plurality of chip pads 230a disposed on an upper surface of each of the plurality of semiconductor chips 200a. The plurality of semiconductor chips 200a may be stacked on the package substrate 100 such that the active surface faces upward, that is, in a direction opposite to the package substrate 100. The plurality of semiconductor chips 200a may be stacked on the package substrate 100 such that the inactive surface of the semiconductor substrate 210a faces downward, that is, the package substrate 100.

A plurality of bonding wires 600a may be connected between the plurality of chip pads 230a and the plurality of upper surface connection pads 122UP. The semiconductor chip 200a may be electrically connected to the package substrate 100 through the plurality of bonding wires 600a. The plurality of bonding wires 600a may sequentially connect the plurality of chip pads 230a of each of the semiconductor chips 200a from the plurality of chip pads 230a of the uppermost semiconductor chip 200a to the plurality of chip pads 230a of the lowermost semiconductor chip 200a, and then connect the plurality of chip pads 230a of the lowermost semiconductor chip 200a to the plurality of upper surface connection pads 122UP.

The plurality of semiconductor chips 200a may have a plurality of die adhesive films 280a attached onto lower surfaces thereof therebetween and be attached onto a lower structure thereof. For example, the lowermost semiconductor chip 200a among the plurality of semiconductor chips 200a may have a die adhesive film 280a therebetween and be attached onto the package substrate 100, and each of the remaining semiconductor chips 200a may have the die adhesive film 280a therebetween and be attached onto the other semiconductor chip 200a.

The molding layer 700 covering an upper surface of the package substrate 100 and surrounding the plurality of semiconductor chips 200a and the plurality of bonding wires 600a may be disposed on the package substrate 100. The electromagnetic wave shielding layer 900 may integrally cover side surfaces of the package substrate 100 and side surfaces and an upper surface of the molding layer 700.

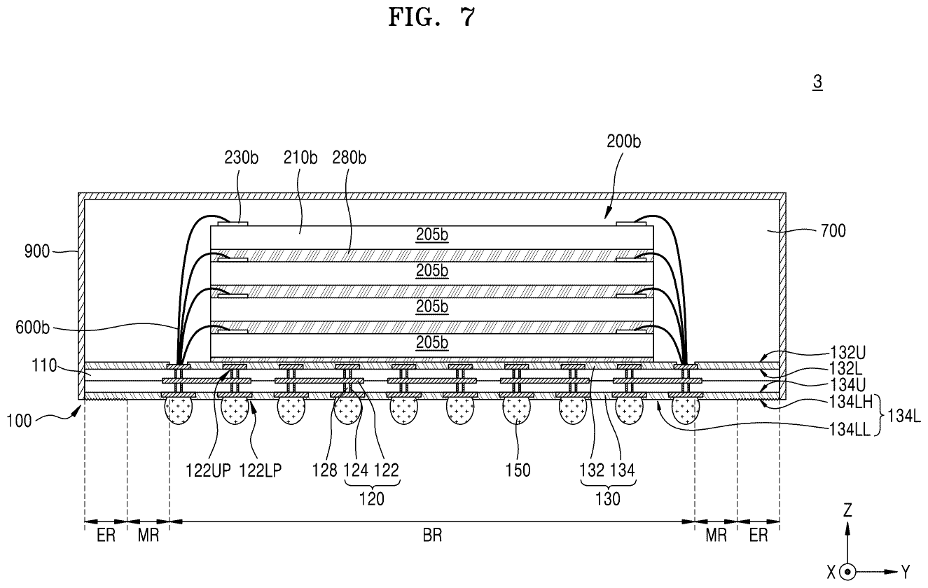

FIG. 7 is a cross-sectional view illustrating a semiconductor package according to embodiments.

Referring to FIG. 7, a semiconductor package 3 includes the package substrate 100, a plurality of semiconductor chips 200b, the molding layer 700, and the electromagnetic wave shielding layer 900. The package substrate 100 includes the solder resist layer 130 covering an upper surface and a lower surface of the substrate base 110. The lower surface 134L of the lower solder resist layer 134 may include the first lower surface region 134LH and the second lower surface region 134LL.

The plurality of semiconductor chips 200b may be sequentially stacked on the package substrate 100 in the vertical direction (Z direction). The plurality of semiconductor chips 200b may be stacked to be aligned with each other in the vertical direction (Z direction). For example, edges of the plurality of semiconductor chips 200b may be aligned with each other in the vertical direction (Z direction). Each of the plurality of semiconductor chips 200b may include a semiconductor device 205b located on an active surface of a semiconductor substrate 210b. The semiconductor device 205b may be a memory semiconductor device. For example, the semiconductor chip 200b may be a memory semiconductor chip. In some embodiments, the semiconductor device 205b may be a nonvolatile memory semiconductor device such as DRAM.

Each of the plurality of semiconductor chips 200b may include a plurality of chip pads 230b disposed on an upper surface of each of the plurality of semiconductor chips 200b. Each of the plurality of semiconductor chips 200b may be stacked on the package substrate 100 such that the active surface faces upward, that is, a direction opposite to the package substrate 100. Each of the plurality of semiconductor chips 200b may be stacked on the package substrate 100 such that the inactive surface of the semiconductor substrate 210a faces downward, that is, the package substrate 100.

The plurality of semiconductor chips 200b may have a plurality of die adhesive films 280b attached onto lower surfaces thereof therebetween and be attached onto a lower structure thereof. For example, the lowermost semiconductor chip 200b among the plurality of semiconductor chips 200b may have the die adhesive film 280b therebetween and be attached onto the package substrate 100, and each of the remaining semiconductor chips 200b may have the die adhesive film 280b therebetween and be attached onto the other lower semiconductor chip 200b.

A plurality of bonding wires 600b may be connected between the plurality of chip pads 230b and the plurality of upper surface connection pads 122UP. The semiconductor chip 200b may be electrically connected to the package substrate 100 through the plurality of bonding wires 600b. The plurality of bonding wires 600b may connect between the plurality of chip pads 230b of the plurality of semiconductor chips 200b and the plurality of upper surface connection pads 122UP. The plurality of chip pads 230b of the semiconductor chip 200b, except for the uppermost semiconductor chip 200b, and a part adjacent to the plurality of chip pads 230b among the bonding wires 600b connected thereto may be buried in the die adhesive film 280b.

The molding layer 700 covering the upper surface of the package substrate 100 and surrounding the plurality of semiconductor chips 200b and the plurality of bonding wires 600b may be disposed on the package substrate 100. The electromagnetic wave shielding layer 900 may integrally cover side surfaces of the package substrate 100 and side surfaces and an upper surface of the molding layer 700.

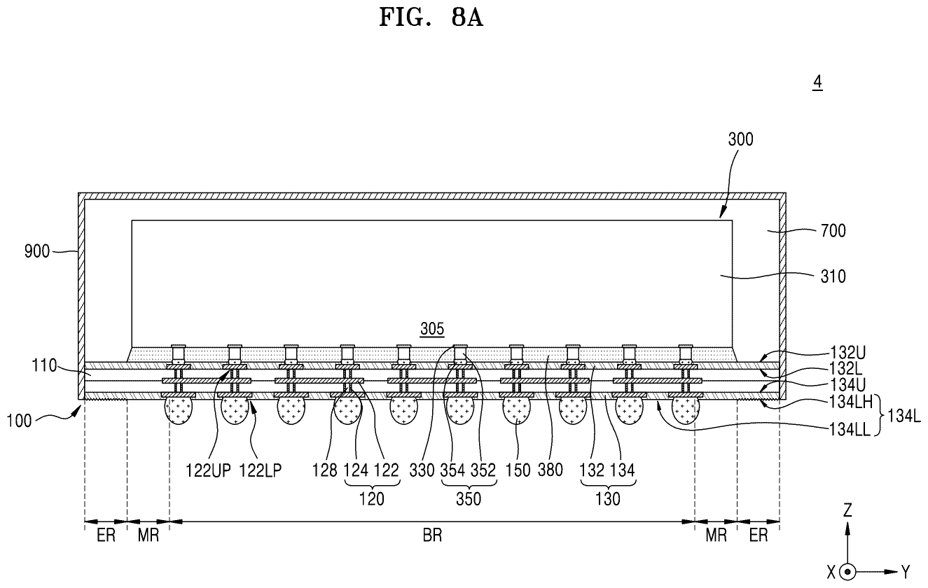

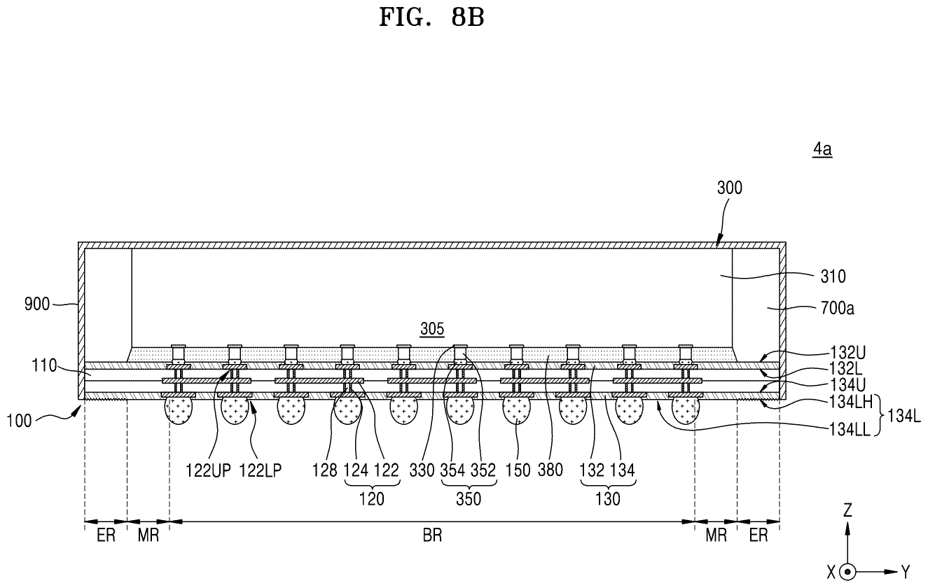

FIGS. 8A and 8B are cross-sectional views illustrating semiconductor packages according to embodiments.

Referring to FIG. 8A, a semiconductor package 4 includes the package substrate 100, at least one semiconductor chip 300, the molding layer 700, and the electromagnetic wave shielding layer 900. The at least one semiconductor chip 300 may include a semiconductor substrate 310. The semiconductor substrate 310 may include a semiconductor material such as a group IV semiconductor material, a group III-V semiconductor material, a group II-VI semiconductor material, or a group II-VI oxide semiconductor material. The at least one semiconductor chip 300 may be attached onto the package substrate 100a. The molding layer 700 may surround the at least one semiconductor chip 300 on the package substrate 100. The electromagnetic wave shielding layer 900 may cover the package substrate 100 and the molding layer 700.

The at least one semiconductor chip 300 may include a plurality of chip pads 330 disposed on an active surface of the semiconductor substrate 310. The semiconductor chip 300 may be attached onto the package substrate 100 such that a plurality of chip pads 330 face the package substrate 100. For example, the semiconductor chip 300 may be attached onto the package substrate 100 so that the active surface of the semiconductor substrate 310 faces the package substrate 100. The plurality of chip connection terminals 350 may be disposed between the plurality of chip pads 330 and the plurality of upper surface connection pads 122UP to electrically connect the semiconductor chip 300 to the package substrate 100. The plurality of chip pads 330 may be electrically connected to a semiconductor device 305. In some embodiments, each of the plurality of chip connection terminals 350 may include a conductive pillar 352 on the chip pad 330 and a conductive cap 354 on the conductive pillar 352. The conductive cap 354 may be in contact with the upper surface connection pad 122UP. For example, the conductive pillar 352 may include at least one of copper, nickel, palladium, platinum, and gold. For example, the conductive cap 354 may include at least one of tin (Sn), indium (In), bismuth (Bi), antimony (Sb), copper (Cu), silver (Ag), gold (Au), zinc (Zn), and lead (Pb).

In some embodiments, an underfill layer 380 may be disposed between the package substrate 100 and the semiconductor chip 300 to surround the plurality of chip connection terminals 350 and fill between the package substrate 100 and the semiconductor chip 300. The underfill layer 380 may include a resin. For example, the underfill layer 380 may include an epoxy resin by a capillary underfill method. In some embodiments, a filler may be mixed in the underfill layer 380, and may include, for example, silica. In some embodiments, the semiconductor package 4 may not include the underfill layer 380, and the molding layer 700 may form a molded underfill (MUF) surrounding the plurality of chip connection terminals 350 and disposed between the package substrate 100 and the semiconductor chip 300.

The molding layer 700 covering an upper surface of the package substrate 100 and surrounding the at least one semiconductor chip 300 may be disposed on the package substrate 100. The electromagnetic wave shielding layer 900 may integrally cover side surfaces of the package substrate 100 and side surfaces and an upper surface of the molding layer 700.

Referring to FIG. 8B, a semiconductor package 4a includes the package substrate 100, the at least one semiconductor chip 300, a molding layer 700a, and the electromagnetic wave shielding layer 900. After the molding layer 700 covering side surfaces and an upper surface of the at least one semiconductor chip 300 is formed as shown in FIG. 8A, the molding layer 700a covering the side surfaces of the at least one semiconductor chip 300 may be formed as shown in FIG. 8B by removing an upper portion of the at least one semiconductor chip 300 and an upper portion of the molding layer 700. The molding layer 700a may surround the side surfaces of the at least one semiconductor chip 300 on the package substrate 100. The electromagnetic wave shielding layer 900 may cover the package substrate 100, the at least one semiconductor chip 300, and the molding layer 700a. For example, the electromagnetic wave shielding layer 900 may cover side surfaces of the package substrate 100, side surfaces and an upper surface of the molding layer 700a, and an upper surface of the at least one semiconductor chip 300.

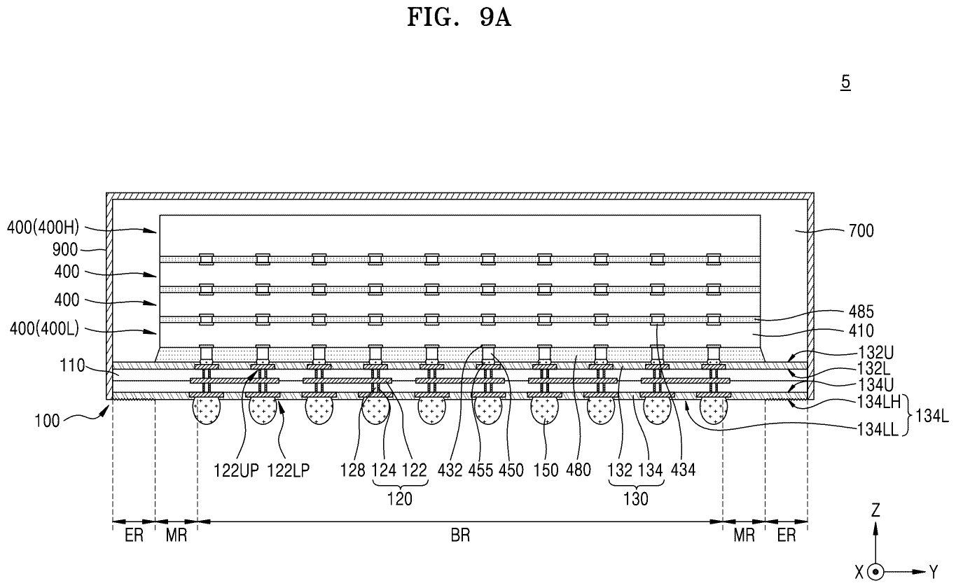

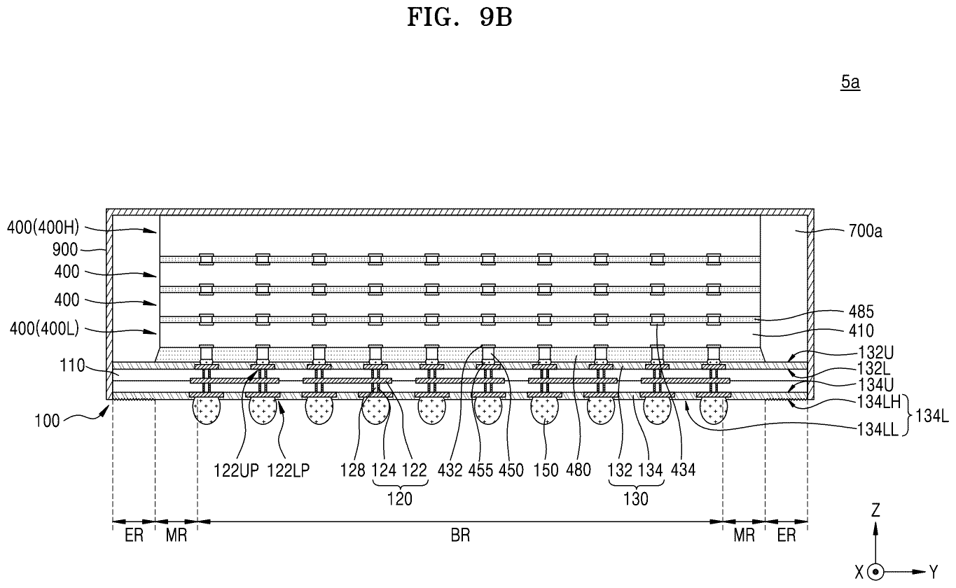

FIGS. 9A and 9B are cross-sectional views illustrating semiconductor packages according to embodiments.

Referring to FIG. 9, a semiconductor package 5 includes the package substrate 100, a plurality of semiconductor chips 400, the molding layer 700, and the electromagnetic wave shielding layer 900. Each of the plurality of semiconductor chips 400 includes a semiconductor substrate 410, a plurality of front chip pads 432, and a plurality of rear chip pads 434. Each of the plurality of front chip pads 432 and the plurality of rear chip pads 434 may be disposed on an active surface and an inactive surface of the semiconductor substrate 410. Each of the plurality of semiconductor chips 400 may include a plurality of through electrodes electrically connecting the plurality of front chip pads 432 and the plurality of rear chip pads 434 corresponding to each other. In some embodiments, an uppermost semiconductor chip 400H among the plurality of semiconductor chips 400 may not include the plurality of rear chip pads 434 and the plurality of through electrodes. In some embodiments, a thickness of the uppermost semiconductor chip 400H among the plurality of semiconductor chips 400 may have a value greater than a thickness of each of the remaining semiconductor chips 400.

The semiconductor substrate 410 may include a semiconductor material such as a group IV semiconductor material, a group III-V semiconductor material, a group II-VI semiconductor material, and a group II-VI oxide semiconductor material. The plurality of semiconductor chips 400 may be sequentially stacked on the package substrate 100 in the vertical direction (Z direction). The plurality of semiconductor chips 400 may be stacked to be aligned with each other in the vertical direction (Z direction). For example, edges of the plurality of semiconductor chips 400 may be aligned with each other in the vertical direction (Z direction). Each of the plurality of semiconductor chips 400 may include a semiconductor device located on the active surface of the semiconductor substrate 410. For example, at least some of the plurality of semiconductor chips 400 may be memory semiconductor chips. In some embodiments, at least some of the plurality of semiconductor chips 400 may include nonvolatile memory semiconductor devices such as DRAM. The plurality of semiconductor chips 400 may be sequentially stacked such that the active surface of the semiconductor substrate 410 faces downward, that is, the package substrate 100.

A lowermost semiconductor chip 400L among the plurality of semiconductor chips 400 may not include a memory cell. The lowermost semiconductor chip 400L may include a serial-parallel conversion circuit, a test logic circuit such as design for test (DFT), Joint Test Action Group (JTAG), and memory built-in self-test (MBIST), and a signal interface circuit such as PHY The remaining semiconductor chips 400 except for the lowermost semiconductor chip 400L among the plurality of semiconductor chips 400 may include memory cells. For example, the lowermost semiconductor chip 400L may be a buffer chip for controlling the remaining semiconductor chips 400. In some embodiments, the lowermost semiconductor chip 400L may be a buffer chip for controlling HBM DRAM, and the remaining semiconductor chips 400L may be memory cell chips having cells of HBM DRAM controlled by the lowermost semiconductor chip 400L. The lowermost semiconductor chip 400L may be referred to as a buffer chip or a master chip, and the remaining semiconductor chips 400 may be referred to as a slave chip or a memory cell chip. A stack structure including the plurality of semiconductor chips 400 may be referred to as an HBM DRAM device.

A plurality of chip connection terminals 450 may be attached onto the plurality of front chip pads 432. The plurality of chip connection terminals 450 attached onto the plurality of front chip pads 432 of the lowermost semiconductor chip 400L among the plurality of semiconductor chips 400 may be connected to the plurality of upper surface connection pads 122UP of the substrate base 110, and the plurality of front chip pads 432 of the remaining semiconductor chips 400 may be connected to the plurality of rear chip pads 434 of another lower semiconductor chip 400.

An adhesive layer 485 may be disposed between each of the plurality of semiconductor chips 400. In some embodiments, each of the plurality of chip connection terminals 450 may be a bump, a solder ball, etc., and the adhesive layer 485 may include a nonconductive film (NCF), a nonconductive paste (NCP), an insulating polymer, or an epoxy resin. The adhesive layer 485 may surround the plurality of chip connection terminals 450 and fill between each of the plurality of semiconductor chips 400. In some embodiments, the adhesive layer 485 and the plurality of chip connection terminals 450 may be formed in a hybrid bonding manner. For example, a lower part of the adhesive layer 485 and a lower part of each of the plurality of chip connection terminals 450 may be formed on the lower semiconductor chip 400, and an upper part of the adhesive layer 485 and an upper part of each of the plurality of chip connection terminals 450 may be formed below the upper semiconductor chip 400. The lower part and the upper part of the adhesive layer 485 may be covalently bonded to form the adhesive layer 485. The lower parts and the upper parts of the plurality of chip connection terminals 450 corresponding to each other may face each other and then thermally expand to be in contact with each other, and be diffusely bonded to be integrated through diffusion of metal atoms included therein such that the plurality of chip connection terminals 450 may be formed in which the lower parts and the upper parts corresponding to each other are combined.

In some embodiments, an underfill layer 480 may be disposed between the package substrate 100 and the lowermost semiconductor chip 400L to surround the plurality of chip connection terminals 450 of the lowermost semiconductor chip 400L and to fill between the package substrate 100 and the lowermost semiconductor chip 400L. The molding layer 700 covering an upper surface of the package substrate 100 and surrounding the plurality of semiconductor chips 400 may be disposed on the package substrate 100. The electromagnetic wave shielding layer 900 may integrally cover side surfaces of the package substrate 100 and side surfaces and an upper surface of the molding layer 700.

Referring to FIG. 9B, a semiconductor package 5a includes the package substrate 100, the plurality of semiconductor chips 400, the molding layer 700a, and the electromagnetic wave shielding layer 900. After the molding layer 700 covering side surfaces and upper surfaces of the plurality of semiconductor chips 400 is formed as shown in FIG. 9A, the molding layer 700a covering the side surfaces of at least the plurality of semiconductor chips 400 may be formed as shown in FIG. 9B by removing an upper portion of the uppermost semiconductor chip 400H among the plurality of semiconductor chips 400 and an upper portion of the molding layer 700. The molding layer 700a may surround the side surfaces of the plurality of semiconductor chips 400 on the package substrate 100. The electromagnetic wave shielding layer 900 may cover the package substrate 100, the plurality of semiconductor chips 400, and the molding layer 700a. For example, the electromagnetic wave shielding layer 900 may cover side surfaces of the package substrate 100, side surfaces and an upper surface of the molding layer 700a, and an upper surface of the uppermost semiconductor chip 400H among the plurality of semiconductor chips 400.

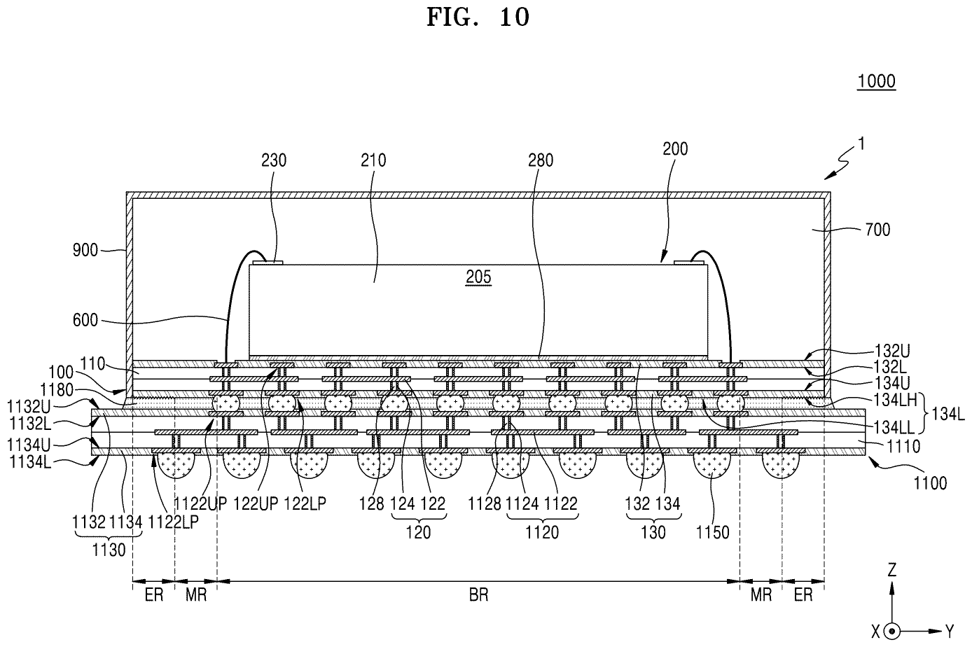

FIG. 10 is a cross-sectional view illustrating an electronic system including a semiconductor package according to embodiments.

Referring to FIG. 10, an electronic system 1000 includes a system substrate 1100 and the semiconductor package 1 attached onto the system substrate 1100. In FIG. 10, the electronic system 1000 includes the semiconductor package 1 shown in FIGS. 1A and 1B attached onto the system substrate 1100, but is not limited thereto. For example, the electronic system 1000 may include the semiconductor packages 1a, 1b, 1c, 1d, 1e, 1f, 1g, 1h, 1i, and 1j shown in FIGS. 3A to 3H, or the semiconductor packages 2, 3, 4, 4a, 5, and 5a shown in FIGS. 6 to 9B, instead of the semiconductor package 1 shown in FIGS. 1A and 1B.

The system substrate 1100 may be a printed circuit board. For example, the system substrate 1100 may be a double-sided printed circuit board or a multi-layer printed circuit board. The system substrate 1100 may include at least one system substrate base 1110, a system substrate wiring structure 1120 including a plurality of system substrate wiring patterns 1122 and a plurality of system substrate via patterns 1124, and a system solder resist layer 1130 including an upper system solder resist layer 1132 and a lower system solder resist layer 1134. Some of the system substrate wiring patterns 1122 disposed on an upper surface of the system substrate base 1110 may be a plurality of upper system connection pads 1122UP, and some of the system substrate wiring patterns 1122 disposed on a lower surface of the system substrate base 1110 may be a plurality of lower system connection pads 1122LP. The system substrate base 1110, the system substrate wiring structure 1120, and the system solder resist layer 1130 included in the system substrate 1100 are generally similar to the substrate base 110, the substrate wiring structure 120, and the solder resist layer 130 included in the package substrate 100, respectively, and thus redundant descriptions thereof are omitted.

The upper system solder resist layer 1132 may have an upper surface 1132U and a lower surface 1132L. The lower surface 1132L of the upper system solder resist layer 1132 may be in contact with the upper surface of the system substrate base 1110. The lower system solder resist layer 1134 may have an upper surface 1134U and a lower surface 1134L. The upper surface 1134U of the lower system solder resist layer 1134 may be in contact with the lower surface of the system substrate base 1110. Unlike the lower surface 134L of the lower solder resist layer 134, the lower surface 1134L of the lower system solder resist layer 1134 may not include a region with the arithmetic average roughness R that is at least twice greater than another region thereof. For example, the arithmetic average roughness Ra of the lower surface 1134L of the lower system solder resist layer 1134 may be substantially the same as or similar to the arithmetic average roughness Ra of the second lower surface region 134LL of the lower surface 134L of the lower solder resist layer 134.

The plurality of package connection terminals 150 may be attached onto the plurality of upper system connection pads 1122UP, and the plurality of system connection terminals 1150 may be attached onto the plurality of lower system connection pads 1122LP. A system underfill layer 1180 may be disposed between the package substrate 100 and the system substrate 1100 to surround the plurality of package connection terminals 150 and fill between the package substrate 100 and the system substrate 1100. The system underfill layer 1180 may fill between the lower surface 134L of the lower solder resist layer 134 and the upper surface 1132U of the upper system solder resist layer 1132. A part of an upper surface of the system underfill layer 1180 may be in contact with the first lower surface region 134LH of the lower surface 134L of the lower solder resist layer 134. The first lower surface region 134LH has a relatively large arithmetic average roughness Ra, and thus a part of the upper surface of the system underfill layer 1180 in contact with the first lower surface region 134LH may have a relatively large adhesive force to the package substrate 100.

Therefore, the electronic system 1000 according to the inventive concept may have structural reliability and electrical connection reliability between the semiconductor package 1 and the system substrate 1100 because the adhesion between the semiconductor package 1 and the system substrate 1100 is relatively large.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package substrate including a substrate base, a plurality of upper surface connection pads disposed on an upper surface of the substrate base, a plurality of lower surface connection pads disposed on a lower surface of the substrate base and electrically connected to the plurality of corresponding upper surface connection pads, an upper solder resist layer covering the upper surface of the substrate base, and a lower solder resist layer covering the lower surface of the substrate base;
at least one semiconductor chip attached onto the package substrate and electrically connected to the plurality of upper surface connection pads;
a plurality of package connection terminals respectively attached onto the plurality of lower surface connection pads;
a molding layer covering the upper surface of the package substrate and surrounding the at least one semiconductor chip; and
an electromagnetic wave shielding layer covering the package substrate and the molding layer,
wherein a lower surface of the lower solder resist layer has a first lower surface region having a first arithmetic average roughness and a second lower surface region having a second arithmetic average roughness that is less than the first arithmetic average roughness, and
the first lower surface region is spaced apart from the plurality of package connection terminals and disposed along an edge of the package substrate.

2. The semiconductor package of claim 1, wherein the first arithmetic average roughness is at least twice greater than the second arithmetic average roughness.

3. The semiconductor package of claim 2, wherein the first arithmetic average roughness is at least 60 nm greater than the second arithmetic average roughness.

4. The semiconductor package of claim 1, wherein
a first length, which is a shortest distance between the edge of the package substrate and the plurality of package connection terminals in a first horizontal direction, is less than a second length, which is a shortest distance between the edge of the package substrate and the plurality of package connection terminals in a second horizontal direction orthogonal to the first horizontal direction, and
a third length, which is a horizontal width of the first lower surface region in the first horizontal direction, is greater than or equal to ½ of the first length and less than the first length.

5. The semiconductor package of claim 4, wherein a fourth length, which is a shortest distance between the first lower surface region and the plurality of package connection terminals, is greater than or equal to a horizontal width of each of the plurality of package connection terminals.

6. The semiconductor package of claim 4, wherein the lower surface of the lower solder resist layer has at least two first lower surface regions spaced apart from each other with a part of the second lower surface region disposed therebetween.

7. The semiconductor package of claim 6, wherein a separation distance between the at least two first lower surface regions is less than the third length.

8. The semiconductor package of claim 1, wherein the first lower surface region extends continuously along the edge of the package substrate in a plan view.

9. The semiconductor package of claim 1, wherein the electromagnetic wave shielding layer covers an upper surface and side surfaces of the molding layer and side surfaces of the package substrate, wherein the electromagnetic wave shielding layer does not cover the lower surface of the package substrate.

10. The semiconductor package of claim 9, wherein the electromagnetic wave shielding layer covers an upper surface of the at least one semiconductor chip.

11. A semiconductor package comprising:
a package substrate including a substrate base, a plurality of upper surface connection pads disposed on an upper surface of the substrate base, a plurality of lower surface connection pads disposed on a lower surface of the substrate base and electrically connected to the plurality of corresponding upper surface connection pads, an upper solder resist layer covering the upper surface of the substrate base, and a lower solder resist layer covering the lower surface of the substrate base;
at least one semiconductor chip attached onto the package substrate and electrically connected to the plurality of upper surface connection pads;
a plurality of package connection terminals attached onto the plurality of lower surface connection pads;
a molding layer covering the upper surface of the package substrate and surrounding the at least one semiconductor chip; and
an electromagnetic wave shielding layer covering the package substrate and the molding layer,
wherein a lower surface of the lower solder resist layer has a first lower surface region having a first arithmetic average roughness and spaced apart from the plurality of package connection terminals, and a second lower surface region having a second arithmetic average roughness that is less than the first arithmetic average roughness,
a first length, which is a shortest distance between an edge of the package substrate and the plurality of package connection terminals in a first horizontal direction, is less than a second length, which is a shortest distance between the edge of the package substrate and the plurality of package connection terminals in a second horizontal direction orthogonal to the first horizontal direction, and
the first lower surface region has a horizontal width greater than or equal to ½ of the first length and is disposed along the edge of the package substrate.

12. The semiconductor package of claim 11, wherein
an upper surface of the upper solder resist layer has a third arithmetic average roughness, and
the first arithmetic average roughness is at least twice greater than each of the second arithmetic average roughness and the third arithmetic average roughness.

13. The semiconductor package of claim 11, wherein
each of the second arithmetic average roughness and the third arithmetic average roughness is 50 nm or less, and
the first arithmetic average roughness is at least 60 nm greater than each of the second arithmetic average roughness and the third arithmetic average roughness.

14. The semiconductor package of claim 11, wherein a shortest distance between the first lower surface region and the plurality of package connection terminals is greater than or equal to a horizontal width of each of the plurality of package connection terminals.

15. The semiconductor package of claim 11, wherein the first lower surface region has a rectangular ring shape extending continuously along the edge of the package substrate in a plan view.

16. The semiconductor package of claim 11, wherein
the first lower surface region includes a plurality of first lower surface regions that are spaced apart from each other, and
each of the plurality of first lower surface regions has any one of an I-shape, an L-shape, or a U-shape in a plan view.

17. The semiconductor package of claim 16, wherein a separation distance between two adjacent first lower surface regions among the plurality of first lower surface regions is less than a horizontal width of the first lower surface region.

18. An electronic system comprising:
a package substrate including a substrate base, a plurality of upper surface connection pads disposed on an upper surface of the substrate base, a plurality of lower surface connection pads disposed on a lower surface of the substrate base and electrically connected to the plurality of corresponding upper surface connection pads, an upper solder resist layer covering the upper surface of the substrate base, and a lower solder resist layer covering the lower surface of the substrate base;
at least one semiconductor chip attached onto the package substrate and electrically connected to the plurality of upper surface connection pads;
a plurality of package connection terminals attached onto the plurality of lower surface connection pads;
a molding layer covering the upper surface of the package substrate and surrounding the at least one semiconductor chip;
an electromagnetic wave shielding layer covering the package substrate and the molding layer;
a system substrate including a system substrate base, a plurality of upper system connection pads disposed on an upper surface of the system substrate base, the plurality of package connection terminals being attached onto the plurality of upper system connection pads, an upper system solder resist layer covering the upper surface of the system substrate base, and a lower system solder resist layer covering a lower surface of the system substrate base; and
a system underfill layer surrounding the plurality of package connection terminals and disposed between the package substrate and the system substrate,
wherein a lower surface of the lower solder resist layer has a first lower surface region having a first arithmetic average roughness and a second lower surface region having a second arithmetic average roughness that is less than the first arithmetic average roughness,
the first lower surface region is spaced apart from the plurality of package connection terminals and disposed along an edge of the package substrate, and
a part of an upper surface of the system underfill layer is in contact with the first lower surface region.

19. The electronic system of claim 18, wherein
a first length, which is a shortest distance between the edge of the package substrate and the plurality of package connection terminals in a first horizontal direction, is less than a second length, which is a shortest distance between the edge of the package substrate and the plurality of package connection terminals in a second horizontal direction orthogonal to the first horizontal direction, and
the first lower surface region has a horizontal width greater than or equal to ½ of the first length and less than the first length, and
a shortest distance between the first lower surface region and the plurality of package connection terminals is greater than or equal to a horizontal width of each of the plurality of package connection terminals.

20. The electronic system of claim 18, wherein
the second arithmetic average roughness is 50 nm or less, and
the first arithmetic average roughness is at least 60 nm greater than the second arithmetic average roughness.
